(19) United States
(12) Patent Application Publication
(10) Pub. No.: US 2026/0362883 A1
(43) Pub. Date: Nov. 12, 2026

(54) DISPLAY APPARATUS, METHOD FOR MANUFACTURING DISPLAY APPARATUS AND ELECTRONIC DEVICE

(71) Applicant: Samsung Display Co., LTD., Yongin-si (KR)

(72) Inventors: Jinwoo CHOI, Yongin-si (KR); Gana KIM, Yongin-si (KR); Jangyeol YOON, Yongin-si (KR); Kangyoung LEE, Yongin-si (KR); Gyujeong LEE, Yongin-si (KR)

(21) Appl. No.: 19/447,306

(22) Filed: Jan. 13, 2026

(30) Foreign Application Priority Data
Jan. 13, 2025 (KR) 10-2025-0004980

(51) Int. Cl. H10H 29/49; H10H 29/01; H10H 29/85

(52) U.S. Cl. CPC H10H 29/49; H10H 29/012; H10H 29/0364; H10H 29/8508

(57) ABSTRACT

A display apparatus includes an island portion in which a light-emitting diode is arranged, and a bridge portion connecting the island portion to an adjacent another island portion, and the island portion includes a base layer directly connected to the bridge portion, and a pixel layer arranged on the base layer and overlapping both the base layer and at least a portion of the bridge portion in a plan view.

This application claims priority to Korean Patent Application No. 10-2025-0004980, filed on Jan. 13, 2025, and all the benefits accruing therefrom under 35 U.S.C. § 119, the content of which in its entirety is herein incorporated by reference.

### BACKGROUND

### Technical Field

The present disclosure relates to an apparatus and a method, and more particularly, to a display apparatus, a method of manufacturing the display apparatus, and an electronic device including the display apparatus.

### Background Art

Recently, electronic devices have been widely used. Electronic devices are widely used in various forms, such as portable and fixed configurations. Such electronic devices include display apparatuses capable of providing users with visual information, such as still images or moving images, so as to support various functions.

With the developments in display apparatuses that visually display electrical signals, various display apparatuses with excellent features, such as small thickness, light weight, and low power consumption, have been introduced. For example, flexible display apparatuses that are bendable or rollable have been introduced. Significant progress has recently been made in research and development on display apparatuses with diverse structures, such as a stretchable display apparatus that may undergo various deformations.

The background technology stated herein is technical information that the inventor either possessed to develop the present disclosure or acquired in the course of deriving the present disclosure and is not necessarily known to the general public before the filing of the present disclosure.

### SUMMARY

Embodiments of the present disclosure provide a display apparatus that is high-resolution and easily stretchable and an electronic device—for example, a flexible display apparatus and an electronic device—and a method of manufacturing the display apparatus.

However, this is merely an example, and the scope of the present disclosure is not limited thereto.

According to an aspect of the present disclosure, a display apparatus includes an island portion in which a light-emitting diode is arranged, and a bridge portion connecting the island portion to an adjacent another island portion, where the island portion includes a base layer directly connected to the bridge portion, and a pixel layer arranged on the base layer and overlapping both the base layer and at least a portion of the bridge portion in a plan view.

In an embodiment, a lower surface of the pixel layer may be connected to an upper surface of the base layer and spaced apart from an upper surface of the bridge portion.

In an embodiment, a space between the lower surface of the pixel layer and the upper surface of the bridge portion may be filled with an elastic member.

In an embodiment, in the pixel layer, the light-emitting diode and a pixel driving circuit unit, electrically connected to the light-emitting diode and configured to drive the light-emitting diode, may be arranged.

In an embodiment, the pixel driving circuit unit may be electrically connected to wires arranged in the bridge portion through a contact hole in the base layer.

In an embodiment, a side of the pixel layer and a side of the base layer, which corresponds to the side of the pixel layer, may be obliquely inclined with respect to each other in the plan view.

In an embodiment, the pixel layer may be provided in plurality, and the plurality of pixel layers may be arranged parallel to each other in a first direction, and a side of each of the plurality of pixel layers may be parallel to the first direction.

In an embodiment, a side of the base layer may be obliquely inclined with respect to the first direction in the plan view.

In an embodiment, in the plan view, a size of the pixel layer may be greater than a size of the base layer.

In an embodiment, a thickness of the base layer may be greater than a thickness of the bridge portion.

In an embodiment, the base layer may include a substrate and an insulating layer arranged on the substrate.

According to an aspect of the present disclosure, a method manufacturing a display apparatus includes arranging a base layer and a bridge portion directly connected to the base layer, depositing a sacrificial layer over regions other than an upper surface of the base layer, arranging a pixel layer on an upper surface of the base layer and an upper surface of the sacrificial layer, and removing the sacrificial layer.

In an embodiment, the arranging of the pixel layer may include arranging the pixel layer to overlap both the base layer and at least a portion of the bridge portion in a plan view.

In an embodiment, the removing of the sacrificial layer may include spacing a lower surface of the pixel layer apart from an upper surface of the bridge portion.

In an embodiment, in the pixel layer, a light-emitting diode and a pixel driving circuit unit, electrically connected to the light-emitting diode and configured to drive the light-emitting diode, may be arranged.

In an embodiment, the arranging of the pixel layer may include electrically connecting the pixel driving circuit unit to wires, which are arranged in the bridge portion, through a contact hole in the base layer.

In an embodiment, the arranging of the pixel layer comprises arranging a side of the pixel layer and a side of the base layer, which corresponds to the side of the pixel layer, to be obliquely inclined with respect to each other in the plan view.

In an embodiment, the pixel layer may be provided in plurality, and the plurality of pixel layers may be arranged parallel to each other in a first direction, and a side of each of the plurality of the pixel layer may be arranged parallel to the first direction.

In an embodiment, a side of the base layer may be obliquely inclined with respect to the first direction in the plan view.

According to an aspect of the present disclosure, an electronic device includes a display apparatus configured to display an image, and a housing configured to accommodate the display apparatus, where the display apparatus includes an island portion in which a light-emitting diode is arranged, and a bridge portion connecting the island portion to an adjacent another island portion, and the island portion includes a base layer directly connected to the bridge portion, and a pixel layer arranged on the base layer and overlapping the base layer and at least a portion of the bridge portion in a plan view.

Other aspects, features, and advantages other than those described above will become apparent from the following detailed description, claims and drawings for carrying out the disclosure.

According to embodiments of the present disclosure, a display apparatus that is stretchable and recoverable in various directions, an electronic device, and a method of manufacturing the display apparatus may be provided. In addition, as the area where a pixel circuit driving unit and light-emitting diodes may be arranged within the display area increases, the display apparatus may achieve high resolution.

The effects of the present disclosure are not limited to those stated herein, and other effects that are not mentioned may be clearly understood by one of ordinary skill in the art from the description of claims.

### DESCRIPTION OF DRAWINGS

FIG. 1 is a schematic perspective view of a display apparatus according to an embodiment of the present disclosure.

FIGS. 2A and 2B are perspective views illustrating the display apparatus of FIG. 1 stretched in a first direction.

FIG. 2C is a perspective view illustrating the display apparatus of FIG. 1 stretched in a second direction.

FIG. 2D is a perspective view illustrating the display apparatus of FIG. 1 stretched in the first direction and the second direction.

FIG. 2E is a perspective view illustrating the display apparatus of FIG. 1 stretched in a third direction.

FIG. 3 is a schematic plan view of a display apparatus according to an embodiment of the present disclosure.

FIG. 4 is an enlarged plan view illustrating region IV of FIG. 3 as part of a display apparatus, according to an embodiment of the present disclosure.

FIG. 5 is a schematic cross-sectional view illustrating an island portion and a bridge portion arranged in a display area of a display apparatus, according to an embodiment of the present disclosure, which corresponds to a cross-section taken along line V-V′ of FIG. 4.

FIG. 6 is a schematic perspective view illustrating an island portion and a bridge portion, according to an embodiment of the present disclosure.

FIGS. 7A to 7C are equivalent circuit diagrams of sub-pixels of a display apparatus, respectively, according to an embodiment of the present disclosure.

FIG. 8A is a schematic cross-sectional view of a light-emitting diode of a display apparatus, according to an embodiment of the present disclosure;

FIG. 8B is a schematic cross-sectional view of a light-emitting diode of a display apparatus, according to an embodiment of the present disclosure.

FIGS. 9A to 9D are diagrams schematically illustrating a method of manufacturing a display apparatus, according to an embodiment of the present disclosure.

FIG. 10A is a schematic perspective view of an electronic device including a display apparatus, according to an embodiment of the present disclosure.

FIG. 10B is a schematic block diagram of an electronic device including a display apparatus, according to an embodiment of the present disclosure.

FIGS. 11A to 11I are schematic perspective views illustrating embodiments of electronic devices including display apparatuses, respectively, according to an embodiment of the present disclosure.

### DETAILED DESCRIPTION

As the present disclosure allows for various changes and numerous embodiments, particular embodiments will be shown in the drawings and described in detail in the written description. The attached drawings for illustrating embodiments of the present disclosure are referred to in order to gain a sufficient understanding of the present disclosure, the merits thereof, and the objectives accomplished by the implementation of the present disclosure. The present disclosure may, however, be embodied in many different forms and should not be construed as being limited to the embodiments set forth herein.

Hereinafter, embodiments of the present disclosure will be described in detail with reference to the accompanying drawings. When describing with reference to the drawings, the same or corresponding elements are assigned the same reference symbol, and repeated descriptions thereof are omitted.

Although the terms “first,” “second,” etc. may be used herein to describe various elements, these elements should not be limited by these terms, and these elements are only used to distinguish one element from another.

As used herein, the singular forms “a,” “an,” and “the” are intended to include the plural forms as well, unless the context clearly indicates otherwise.

The terms “comprises” and/or “comprising” used herein specify the presence of stated features or elements, but do not preclude the possibility of addition of one or more other features or elements.

When a layer, region, or element is referred to as being “on” another layer, region, or element, it can be directly or indirectly formed on the other layer, region, or element. That is, for example, intervening layers, regions, or elements may be present.

When a layer, region, or component is referred to as being connected to another layer, region, or component, it can be directly and/or indirectly connected to the other layer, region, or component. That is, for example, intervening layers, regions, or components may be present. Also, when a layer, region, or component is referred to as being electrically connected to another layer, region, or component, it can be electrically and directly and/or indirectly connected to the other layer, region, or component. That is, for example, intervening layers, regions, or components may be present.

Sizes of elements in the drawings may be exaggerated or reduced for convenience of explanation. For example, since sizes and thicknesses of elements in the drawings are arbitrarily illustrated for convenience of explanation, the present disclosure is not limited thereto.

In the embodiments below, the expression “A and/or B” indicates A, B, or both A and B. In addition, the expression such as “at least one of A and B” indicates A, B, or A and B.

In the embodiments below, when a wire is referred to as “extending in a first direction or a second direction,” the wire may extend in a straight line or extend in a zigzag form or in a curve in the first direction or the second direction.

In the embodiments below, “in a plan view” may indicate that a target portion is viewed from above (i.e., view in a thickness direction (z direction) of the display apparatus). In the embodiments below, “in a cross-sectional view” may refer to a side view of a vertical cross-section of a target portion. In the embodiments below, when a first component is referred to as “overlapping” a second component, it is understood that the first component may be arranged on or under the second component.

In the following examples, the x-axis, the y-axis and the z-axis are not limited to three axes of the rectangular coordinate system, and may be interpreted in a broader sense including the same. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

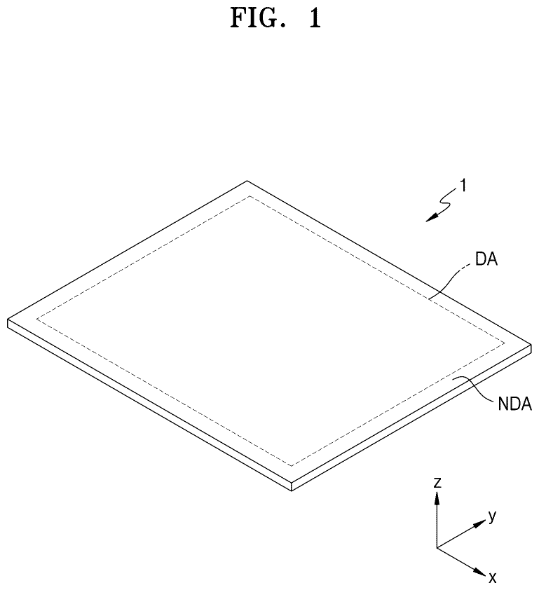

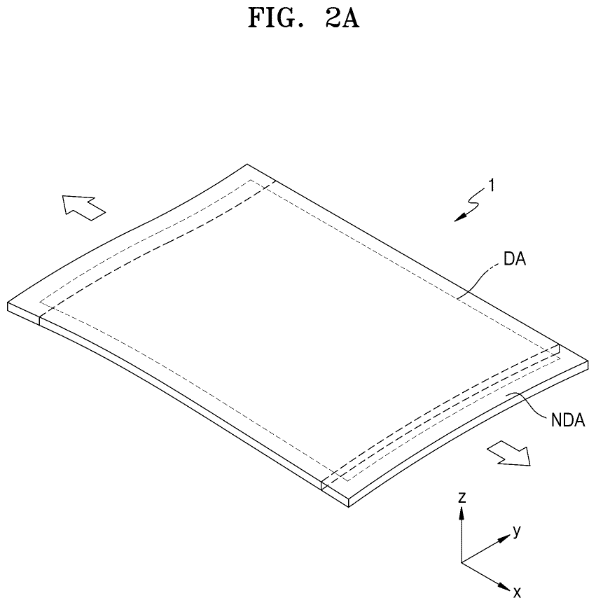

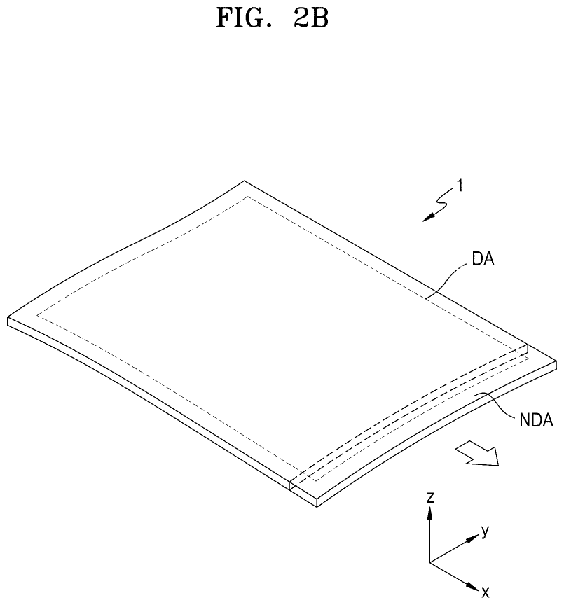

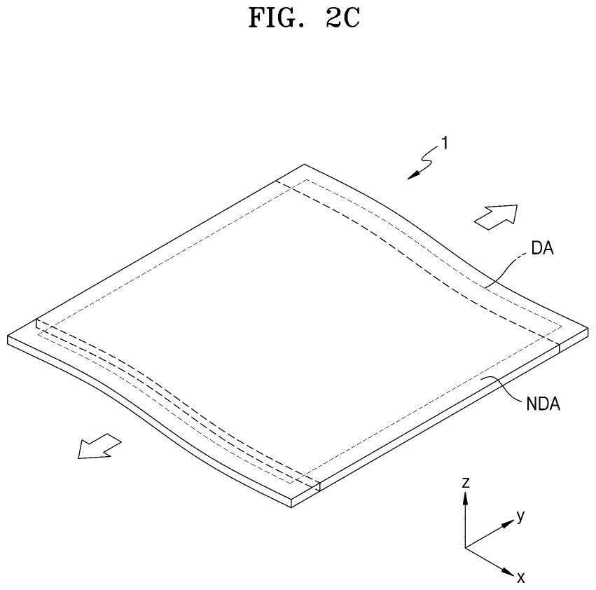

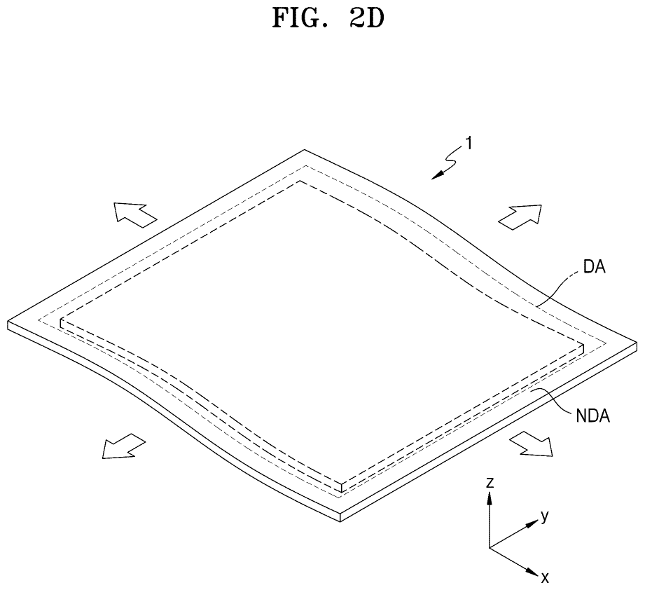

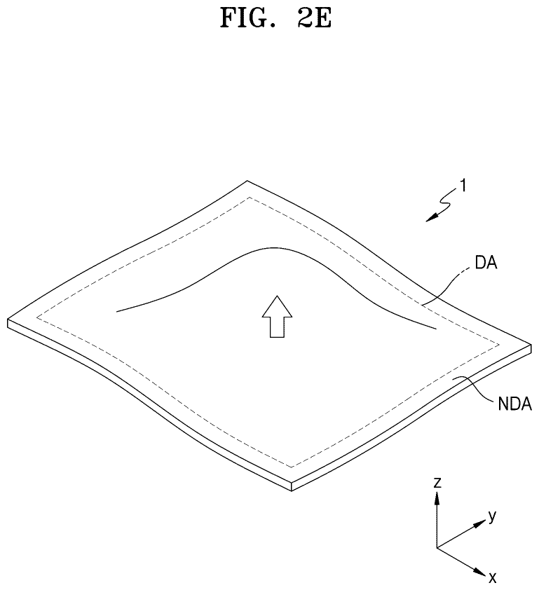

FIG. 1 is a schematic perspective view of a display apparatus 1 according to an embodiment. FIGS. 2A and 2B are perspective views illustrating the display apparatus 1 of FIG. 1 stretched in a first direction. FIG. 2C is a perspective view illustrating the display apparatus 1 of FIG. 1 stretched in a second direction. FIG. 2D is a perspective view illustrating the display apparatus 1 of FIG. 1 stretched in the first direction and the second direction. FIG. 2E is a perspective view illustrating the display apparatus 1 of FIG. 1 stretched in a third direction.

Referring to FIG. 1, the display apparatus 1 may include a display area DA and a non-display area NDA. The display area DA may include a plurality of pixels. The display apparatus 1 may provide a specific image by using light emitted from the plurality of pixels. The non-display area NDA may be outside the display area DA. The non-display area NDA may be an area where no pixels are arranged and may entirely surround the display area DA.

The display apparatus 1 may extend or contract in various directions. The display apparatus 1 may be stretched in the first direction (e.g., the x direction and/or −x direction) by an external force applied by an external object or a user. In an embodiment, as shown in FIGS. 2A and 2B, the display area DA and/or the non-display area NDA of the display apparatus 1 may be stretched in the first direction (e.g., the x direction and/or the −x direction). For example, as shown in FIG. 2A, the display area DA and/or the non-display area NDA of the display apparatus 1 may be stretched in the x direction or −x direction, or as shown in FIG. 2B, the display area DA and/or the non-display area NDA may be stretched in the x direction with one side of the display apparatus 1 fixed.

The display apparatus 1 may be stretched in the second direction (e.g., the y direction and/or −y direction) by an external force applied by an external object or a user. In an embodiment, as shown in FIG. 2C, the display area DA and/or the non-display area NDA of the display apparatus 1 may be stretched in the y direction and the −y direction. In another embodiment, the display area DA and/or the non-display area NDA of the display apparatus 1 may be stretched in the y direction or the −y direction with one side of the display apparatus 1 fixed.

The display apparatus 1 may be stretched in multiple directions, such as the first direction (e.g., the x direction and/or the −x direction) and the second direction (e.g., the y direction and/or the −y direction), by an external force applied by an external object or a body part of a person. As shown in FIG. 2D, the display area DA and/or the non-display area NDA of the display apparatus 1 may be stretched in the ±x direction and the ±y direction.

The display apparatus 1 may be stretched in the third direction (e.g., the z direction or −z direction) by an external force applied by an external object or a body part of a person. In an embodiment, FIG. 2E illustrates that a portion of the display apparatus 1, e.g., a portion of the display area DA, protrudes in the z direction. In another embodiment, a portion of the display apparatus 1, e.g., a portion of the display area DA, may protrude in the −z direction (or may be recessed in the z direction).

FIGS. 2A to 2E illustrate that the display apparatus 1 is stretched in the first direction, the second direction, and/or the third direction, but the present disclosure is not limited thereto. In another embodiment, the display apparatus 1 may be variously deformed into atypical forms; for example, the display apparatus 1 may be bent or twisted around two or more axes.

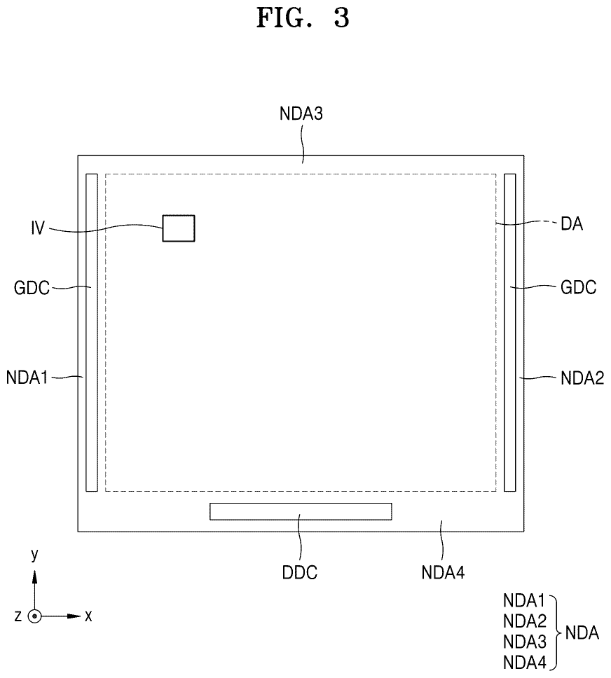

FIG. 3 is a schematic plan view of the display apparatus 1 according to an embodiment.

A plurality of pixels may be arranged in the display area DA of the display apparatus 1. Each pixel may include a plurality of sub-pixels that emit light having different colors. A light-emitting diode corresponding to each sub-pixel may be arranged in the display area DA. In the non-display area NDA around the display area DA, circuits for providing electrical signals to the light-emitting diodes in the display area DA and transistors electrically connected to the light-emitting diodes may be located. Gate driving circuits GDC may be arranged in a first non-display area NDA1 and a second non-display area NDA2 on both sides of the display apparatus 1 with the display area DA therebetween, respectively. The gate driving circuits GDC may include drivers for providing electrical signals to gate electrodes of the transistors that are electrically connected to the light-emitting diodes, respectively. FIG. 3 illustrates that the gate driving circuits GDC are arranged in the first non-display area NDA1 and the second non-display area NDA2, respectively, but the present disclosure is not limited thereto. In another embodiment, the gate driving circuit GDC may be arranged in any one of the first non-display area NDA1 and the second non-display area NDA2.

Data driving circuits DDC may be arranged in a third non-display area NDA3 and/or a fourth non-display area NDA4 that connect the first non-display area NDA1 to the second non-display area NDA2. In embodiment, FIG. 3 illustrates the data driving circuit DDC arranged in the fourth non-display area NDA4. In another embodiment, the data driving circuit DDC may be arranged in each of the third non-display area NDA3 and the fourth non-display area NDA4.

FIG. 3 illustrates that the data driving circuit DDC is arranged in the fourth non-display area NDA4 of the display apparatus 1, but the present disclosure is not limited thereto. In another embodiment, the display apparatus 1 may further include a flexible circuit substrate (not shown) that is electrically connected through a terminal portion (not shown) arranged in the fourth non-display area NDA4, and the data driving circuit DDC may be arranged on the aforementioned flexible circuit substrate.

In some embodiments, the elongation of the non-display area NDA may be the same as or less than the elongation of the display area DA. In an embodiment, the elongation of the non-display area NDA may vary depending on regions. For example, the first non-display area NDA1, the second non-display area NDA2, and the third non-display area NDA3 may have substantially the same elongation, and the elongation of the fourth non-display area NDA4 may be less than the elongations of the first non-display area NDA1, the second non-display area NDA2, and the third non-display area NDA3. In the present specification, elongation refers to a value indicating a change in length ΔL/L by which the display apparatus 1 may be stretched without physical damage thereto when an external force is applied to the display apparatus 1. Here, ΔL refers to the change in length of the display apparatus 1, and L refers to the initial length of the display apparatus 1.

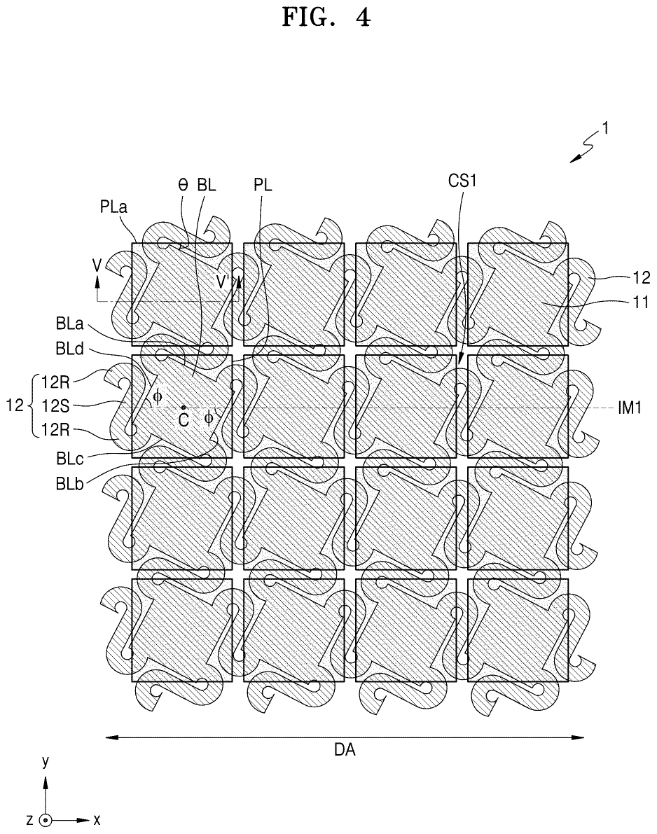

FIG. 4 is an enlarged plan view illustrating region IV of FIG. 3 as part of the display apparatus 1, according to an embodiment.

Referring to FIG. 4, the display apparatus 1 may include a plurality of island portions 11, which are spaced apart from each other in the first direction (e.g., the x direction or −x direction) and the second direction (e.g., the y direction or −y direction), and a plurality of bridge portions 12, which connect adjacent island portions 11 to each other. The bridge portions 12 may be spaced apart from each other by first opening portions CS1 located therebetween.

In an embodiment, each island portion 11 may include a base layer BL and a pixel layer PL arranged on the base layer BL. In an embodiment, the base layer BL may have a rectangular shape, and the bridge portions 12 may be connected to the base layer BL. In addition, the pixel layer PL may also have a square shape and be arranged on the upper portion of the base layer BL.

In an embodiment, at least one side of the base layer BL may be oblique to a virtual line connecting the centers C of the island portions 11 in the first direction (e.g., the x direction or −x direction) and/or the second direction (e.g., the y direction or −y direction). In this regard, FIG. 4 illustrates that each base layer BL includes a first side BLa to a fourth side BLd, and the first side BLa to the fourth side BLd may extend in directions that are oblique to a first virtual line IM1 connecting the centers C of the island portions 11 in a row. In this case, the center C of the island portion 11 may refer to the center of the base layer BL. FIG. 4 illustrates that the first virtual line IM1 extends in the first direction (e.g., the x direction or −x direction), but the first virtual line IM1 may extend in the second direction (e.g., the y direction or −y direction).

In an embodiment, the second side BLb and the fourth side BLd, which are parallel to each other, may cross the first virtual line IM1. The smaller of the angles formed between the second side BLb and the first virtual line IM1 (hereinafter, referred to as a minor angle Φ), may be greater than 0 degrees and less than 90 degrees. The minor angle Φ formed between the fourth side BLd and the first virtual line IM1 may be greater than 0 degrees and less than 90 degrees.

The island portion 11, for example, the base layer BL, may be connected to the bridge portions 12. For example, the base layer BL may be connected to four bridge portions 12. Two bridge portions 12 may be arranged on both sides of the base layer BL along the first direction (e.g., the x direction or −x direction), and the other two bridge portions 12 may be arranged on both sides of the base layer BL along the second direction (e.g., the y direction or −y direction).

Each bridge portion 12 may have a wavy shape. For example, as shown in FIG. 4, the bridge portion 12 may substantially have an ‘S’ shape as the bridge portion 12 includes two round portions 12R and a straight portion 12S between the two round portions 12R.

In an embodiment, as shown in FIG. 4, the straight portion 12S may be substantially parallel to an adjacent side of the base layer BL. For example, the straight portion 12S of each of the bridge portions 12 arranged on both sides of the base layer BL in the first direction (e.g., the x direction or −x direction) may be substantially parallel to the sides (e.g., the second side BLb and the fourth side BLd) of the base layer BL. The straight portion 12S of each of the bridge portions 12 arranged on both sides of the base layer BL in the second direction (e.g., the y direction or −y direction) may be substantially parallel to the sides (e.g., the first side BLa and the third side BLc) of the base layer BL.

It may be understood that each base layer BL shown in FIG. 4 is rotated by a first angle (e.g., an acute angle) with respect to the center C, compared to when the first side BLa is arranged parallel to the first direction (e.g., the x direction or −x direction). Therefore, at least one of the sides of the base layer BL may be oblique to the virtual line connecting the centers C of the base layers BL along the first direction (e.g., the x direction or −x direction) and/or the second direction (e.g., the y direction or −y direction). According to the arrangement of the base layers BL and/or the structure of the bridge portions 12 described above, the area of the first opening portion CS1 shown in FIG. 4 may be relatively less than when the first side BLa of the base layer BL is arranged parallel to the first direction, and thus, the display apparatus 1 according to the embodiment shown in FIG. 4 may provide a relatively high-resolution image.

However, the present disclosure is not limited thereto. In another embodiment, it is apparent that the first sides BLa of the base layers BL are arranged parallel to the first direction and the base layers BL are arranged in parallel in the first virtual line IM1 in the first direction.

FIG. 4 illustrates that the straight portion 12S of the bridge portion 12 is substantially parallel to the side of the base layer BL that is adjacent to the straight portion 12S, but the present disclosure is not limited thereto. In another embodiment, the straight portion 12S of the bridge portion 12 may be oblique to the side of the base layer BL that is adjacent to the straight portion 12S.

In an embodiment, the structure of the first non-display area (NDA1, see FIG. 3) of the display apparatus 1, which is not shown in FIG. 4, may be the same as the structure of the display area DA shown in FIG. 4. In an embodiment, the structure of the first non-display area (NDA1, see FIG. 3) of the display apparatus 1, which is not shown in FIG. 4, may be substantially the same as the structure of the display area DA shown in FIG. 4, but the area of the island portions arranged in the first non-display area (NDA1, see FIG. 3) may be greater than the area of the island portions 11 arranged in the display area DA.

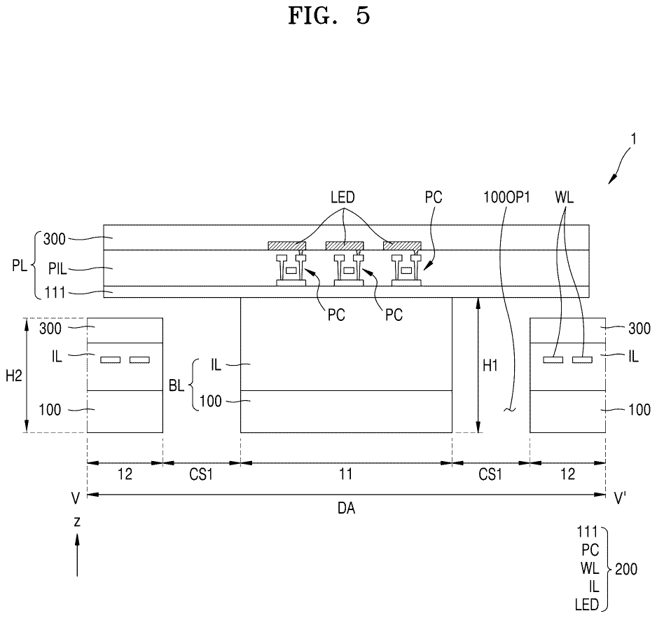

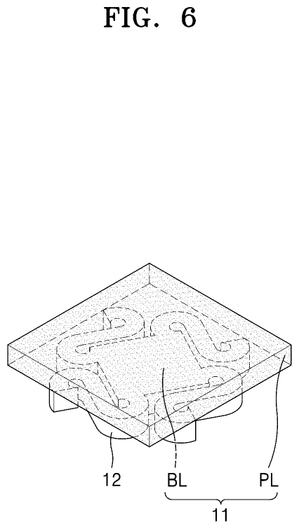

FIG. 5 is a schematic cross-sectional view of an island portion 11 and bridge portions 12 that are arranged in the display area DA of the display apparatus 1, according to an embodiment. FIG. 5 corresponds to the cross-section taken along line V-V′ of FIG. 4. FIG. 6 is a schematic perspective view of the island portion 11 and the bridge portion 12, according to an embodiment.

Referring to FIGS. 4 to 6, the island portion 11 according to an embodiment may include a base layer BL and a pixel layer PL arranged on the base layer BL. The base layer BL may be spaced apart from the bridge portion 12 with a first opening portion CS1 therebetween. The bridge portion 12 may be connected to each side of the base layer BL. The pixel layer PL may include light-emitting diodes LED and a circuit, for example, a pixel driving circuit unit PC, which is electrically connected to the light-emitting diodes LED and configured to drive the same. The bridge portion 12 may include wires WL electrically connected to the pixel driving circuit unit PC arranged in the pixel layer PL.

The base layer BL may include a substrate 100 and an insulating layer IL. The substrate 100 may include polymer resin, such as polyether sulfone, polyarylate, polyetherimide, polyethylene naphthalate, polyethylene terephthalate, polyphenylene sulfide, polyimide, polycarbonate, cellulose triacetate, or cellulose acetate propionate. In an embodiment, the substrate 100 may be a single layer that includes the aforementioned polymer resin. In another embodiment, the substrate 100 may have a multilayered structure that includes a base layer including the aforementioned polymer resin and a barrier layer including an inorganic insulating material. The substrate 100 including polymer resin may be flexible, rollable, or bendable.

The insulating layer IL may be arranged on the substrate 100. In an embodiment, the insulating layer IL may include an organic insulating material. The base layer BL may undergo relatively great deformation along with the bridge portion 12 when the display apparatus 1 is stretched, and thus, the base layer BL may not include a layer that includes an inorganic insulating material and is prone to cracking.

The pixel layer PL may be arranged on the base layer BL. In an embodiment, the pixel layer PL may include a buffer layer 111, the pixel driving circuit unit PC arranged on the buffer layer 111, and a light-emitting diode LED electrically connected to the pixel driving circuit unit PC.

The buffer layer 111 may include an inorganic insulating material, and a pixel insulating layer PIL including an inorganic insulating material and/or an organic insulating material may be arranged between the pixel driving circuit unit PC and the light-emitting diode LED. The light-emitting diode LED may be arranged on the pixel insulating layer PIL and covered by an encapsulation layer 300. The light-emitting diodes LED may emit light having different colors or the same color. In an embodiment, the light-emitting diodes LED may emit red light, green light, and blue light, respectively. In some embodiments, the light-emitting diodes LED may emit white light. In some embodiments, the light-emitting diodes LED may emit red light, green light, blue light, and white light, respectively.

In an embodiment, FIG. 5 illustrates that three pixel driving circuit units PC arranged on each island portion 11 and three light-emitting diodes LED connected to the pixel driving circuit units PC, respectively, but the present disclosure is not limited thereto. In another embodiment, the number of pixel driving circuit units PC arranged on the island portion 11 and the number of light-emitting diodes LED may each be one, two, or at least four.

The encapsulation layer 300 may be arranged on the light-emitting diode LED and protect the same from external forces and/or moisture penetration. The encapsulation layer 300 may include an inorganic encapsulation layer and/or an organic encapsulation layer. In some embodiments, the encapsulation layer 300 may have a stack structure that includes an inorganic encapsulation layer including an inorganic insulating material, an organic encapsulation layer including an organic insulating material, and an inorganic encapsulation layer including an inorganic insulating material. In another embodiment, the encapsulation layer 300 may include an organic material, such as resin. In some embodiments, the encapsulation layer 300 may include urethane epoxy acrylate. The encapsulation layer 300 may include a photosensitive material, such as photoresist.

When the bridge portion 12 is examined, the insulating layer IL including an organic insulating material may be arranged on the substrate 100. The bridge portion 12 that undergoes relatively significant deformation when the display apparatus 1 is stretched may not include a layer that includes an inorganic insulating material and is prone to cracking.

In an embodiment, the substrate 100 corresponding to the bridge portion 12 may have the same stack structure as the substrate 100 corresponding the island portion 11. In an embodiment, the substrate 100 corresponding to the bridge portion 12 and the substrate 100 corresponding to the island portion 11 may be polymer resin layers that are formed together through the same process. In another embodiment, the substrate 100 corresponding to the bridge portion 12 may have a stack structure that is different from a stack structure of the substrate 100 corresponding to the island portion 11. In some embodiments, the substrate 100 corresponding to the island portion 11 may have a multilayered structure that includes a base layer including polymer resin and a barrier layer including an inorganic insulating material, and the substrate 100 corresponding to the bridge portion 12 may have a structure that includes a polymer resin layer but does not include a layer including an inorganic insulating material.

As described above, the wires WL of the bridge portion 12 may be signal lines (e.g., a gate line, a data line, etc.) for providing electrical signals to transistors included in the pixel driving circuit unit PC of the island portion 11 or voltage lines (e.g., a driving voltage line, an initialization voltage line, etc.) for providing voltages. The encapsulation layer 300 may be arranged on the bridge portion 12. In another embodiment, the encapsulation layer 300 may not be arranged on the bridge portion 12.

Referring to FIGS. 4 to 6, the substrate 100 corresponding to the island portion 11 may be connected to the substrate 100 corresponding to the bridge portion 12. In other words, the plan view of FIG. 4 may be substantially the same as the plan view of the substrate 100 of FIG. 5. In other words, the substrate 100 may include the island portions 11, for example, a region corresponding to the base layer BL and a region corresponding to the bridge portion 12, and an opening 100OP1 having the same shape as the first opening portion CS1.

The pixel layer PL may be arranged to be connected to the upper surface of the base layer BL. In an embodiment, each of the base layer BL and the pixel layer PL may have a quadrangular shape, for example, substantially a square shape. In another embodiment, each of the base layer BL and the pixel layer PL may have another polygonal shape, a circular shape, or the like. In addition, the base layer BL may have another polygonal shape or a circular shape, while the pixel layer PL may have a square shape. Hereinafter, for convenience of explanation, a case is described in which each of the base layer BL and the pixel layer PL may have a substantially a square shape.

In this case, in a plan view, the size of the pixel layer PL may be greater than a size of the base layer BL. In other words, in a plan view, one side of the pixel layer PL may be arranged between two adjacent base layers BL. For example, the first side PLa of the pixel layer PL may be located between the first side BLa of the base layer BL corresponding to the pixel layer PL and the third side BLc of the base layer BL that is adjacent to the above base layer BL. In other words, in a plan view, one side of the pixel layer PL may overlap the bridge portion 12 that connects the base layer BL corresponding to the pixel layer PL to another base layer BL that is adjacent to the base layer BL.

In an embodiment, the base layers BL may be arranged parallel to each other in the first direction (e.g., the x direction), and the pixel layers PL arranged on the base layers BL, respectively, may also be arranged parallel to each other in the first direction (e.g., the x direction). In other words, the base layers BL may be arranged parallel to each other along the first virtual line IM1 connecting the centers C of the island portion 11, and the pixel layers PL may also be arranged parallel to each other along the first virtual line IM1.

In this case, one side of the pixel layer PL, for example, the first side PLa, and one side of the base layer BL, for example, the first side BLa, may be obliquely arranged with respect to each other. In other words, the first side PLa of the pixel layer PL and the first side BLa of the base layer BL corresponding to the first side PLa may be obliquely arranged with respect to each other. Here, the side of the base layer BL corresponding to the first side PLa of the pixel layer PL may refer to the side of the base layer BL that is closest to the first side PLa of the pixel layer PL. In an embodiment, the angle θ between the first side PLa of the pixel layer PL and the first side BLa of the base layer BL may be greater than 0 degrees and less than 90 degrees.

In addition, the first side PLa of the pixel layer PL may be arranged parallel to the first virtual line IM1 in the first direction (e.g., the x direction). In this case, the first side BLa of the base layer BL may be inclined obliquely with respect to the first virtual line IM1 in the first direction (e.g., the x direction). It may be understood that the angle obliquely formed by the first side BLa of the base layer BL with respect to the first virtual line IM1 may be the same as the angle θ described above.

The pixel layer PL may be arranged to overlap the entire base layer BL and at least some portions of the bridge portion 12. The pixel layer PL may cover the entire base layer BL and at least some portions of the bridge portion 12. In addition, the pixel layers PL may be arranged to be spaced apart from each other in the first direction (e.g., the x direction).

The pixel layer PL may be spaced apart from the bridge portion 12. For example, the lower surface of the pixel layer PL may be spaced apart from the upper surface of the bridge portion 12 in the third direction (e.g., the z direction). In this case, the thickness H1 of the base layer BL may be greater than the thickness H2 of the bridge portion 12. Accordingly, the pixel layer PL connected to an upper portion of the base layer BL may be spaced apart from the upper surface of the bridge portion 12.

Although not shown in the drawings, the wires WL arranged in the bridge portion 12 may be connected to the base layer BL. In addition, the pixel driving circuit unit PC of the pixel layer PL may be electrically connected to the wires WL through a contact hole defined in the base layer BL. In this case, the contact hole of the base layer BL for connecting the pixel driving circuit unit PC to the wires WL may be defined in a portion of the base layer BL that is connected to the bridge portion 12. That is, in a plan view, the contact hole in the base layer BL may be arranged adjacent to a vertex of the base layer BL.

As such, as the pixel layer PL is arranged on the upper portion of the base layer BL, the pixel layer PL may have a greater size than the base layer BL, and the distance between adjacent pixel layers PL may decrease. In addition, the display apparatus 1 may have a hidden bridge structure in such a manner that the base layer BL and the bridge portion 12 are located under the pixel layer PL before the display apparatus 1 is stretched, but as the display apparatus 1 is stretched, the distance between the pixel layers PL increases, thus exposing the bridge portion 12.

Accordingly, the pixel layer PL may have a greater area and include a greater number of pixel driving circuit units PC and light-emitting diodes LED connected to the pixel driving circuit units PC such that high resolution may be implemented.

In addition, the base layer BL may have a smaller size, and accordingly, the bridge portions 12 may be arranged to be relatively long; thus, the display apparatus 1 having high stretchability may be implemented by the base layer BL and the bridge portion 12. As circuits and similar components (e.g., light-emitting diodes LED and pixel driving circuit units PC), which are relatively restricted in terms of stretching, are arranged in the pixel layer PL, the circuits and the components may be relatively independent from the stretching, and damage thereto may also be prevented.

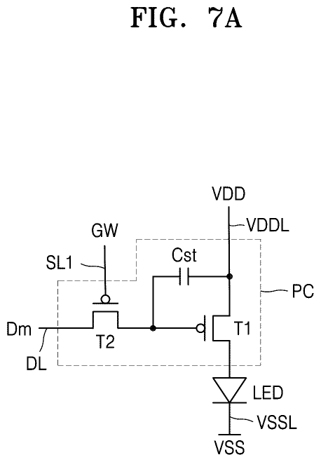

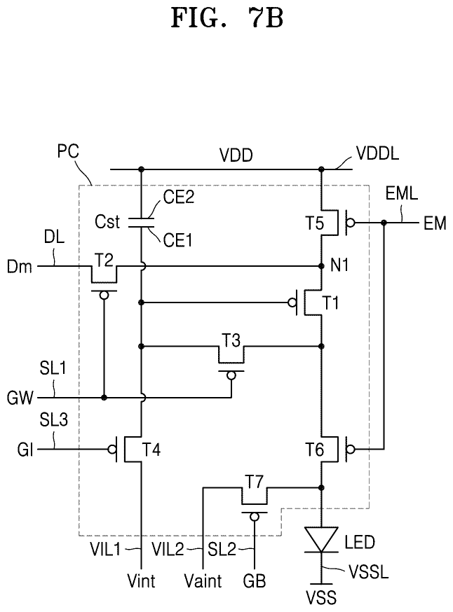

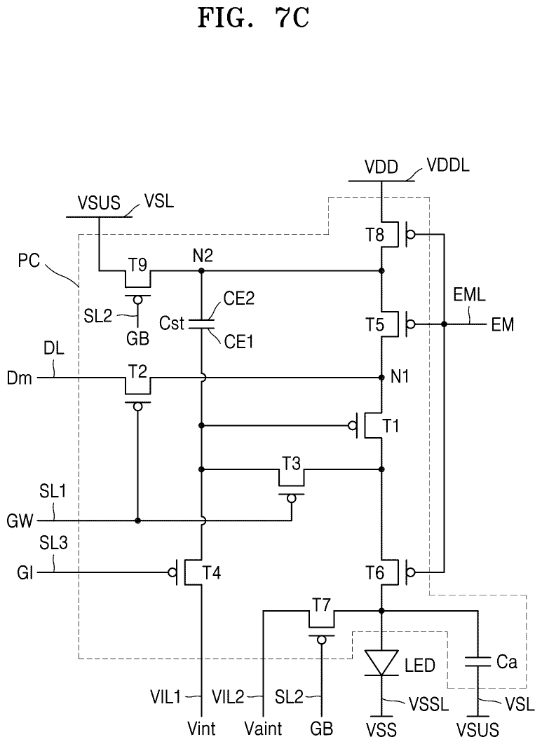

FIGS. 7A to 7C are equivalent circuit diagrams of sub-pixels of the display apparatus 1, respectively, according to an embodiment.

Referring to FIG. 7A, the light-emitting diode LED corresponding to a sub-pixel may be electrically connected to the pixel driving circuit unit PC, and the pixel driving circuit unit PC may include a first transistor T1, a second transistor T2, and a storage capacitor Cst. The pixel driving circuit unit PC may be electrically connected to signal lines and voltage lines. The signal lines may include a gate line, such as a first scan line SL1, and a data line DL, and the voltage line may include a first voltage line VDDL.

The second transistor T2 may be electrically connected to the first scan line SL1 and the data line DL. The first scan line SL1 may be configured to provide a first scan signal GW to a gate electrode of the second transistor T2. The second transistor T2 may be configured to transmit a data signal Dm, which is input through the data line DL, to the first transistor T1 according to the first scan signal GW input through the first scan line SL1.

The storage capacitor Cst may be electrically connected to the second transistor T2 and the first voltage line VDDL and may be configured to store a voltage corresponding to a difference between a voltage from the second transistor T2 and a first power voltage VDD provided through the first voltage line VDDL.

The first transistor T1 may be a driving transistor and configured to control a driving current flowing through the light-emitting diode LED. The first transistor T1 may be connected to the first voltage line VDDL and the storage capacitor Cst. The first transistor T1 may control a driving current flowing from the first voltage line VDDL to the light-emitting diode LED, according to the voltage stored in the storage capacitor Cst. The light-emitting diode LED may emit light having a certain brightness because of the driving current. A first electrode of the light-emitting diode LED may be electrically connected to the first transistor T1, and a second electrode of the light-emitting diode LED may be electrically connected to a second voltage line VSSL configured to provide a second power voltage VSS.

FIG. 7A illustrates that the pixel driving circuit unit PC includes two transistors and one storage capacitor, but in another embodiment, the pixel driving circuit unit PC may include three or more transistors.

Referring to FIG. 7B, the pixel driving circuit unit PC may include a first transistor T1, a second transistor T2, a third transistor T3, a fourth transistor T4, a fifth transistor T5, a sixth transistor T6, a seventh transistor T7, and a storage capacitor Cst.

The pixel driving circuit unit PC is electrically connected to the signal lines and the voltage lines. The signal lines may include gate lines, such as a first scan line SL1, a second scan line SL2, a third scan line SL3, and an emission control line EML, and a data line DL. The voltage lines may include a first initialization voltage line VIL1, a second initialization voltage line VIL2, and a first voltage line VDDL.

The first voltage line VDDL may be configured to transmit the first power voltage VDD to the first transistor T1. The first initialization voltage line VIL1 may be configured to transmit, to the pixel driving circuit unit PC, a first initialization voltage Vint configured to initialize the first transistor T1. The second initialization voltage line VIL2 may be configured to transmit, to the pixel driving circuit unit PC, a second initialization voltage Vaint configured to initialize the first electrode of the light-emitting diode LED.

The first transistor T1 may be electrically connected to the first voltage line VDDL via the fifth transistor T5 and to the light-emitting diode LED via the sixth transistor T6. The first transistor T1 functions as a driving transistor and receives a data signal Dm according to a switching operation of the second transistor T2, thereby providing a driving current to the light-emitting diode LED.

The second transistor T2 is a data write transistor and electrically connected to the first scan line SL1 and the data line DL. The second transistor T2 is electrically connected to the first voltage line VDDL via the fifth transistor T5. The second transistor T2 is turned on in response to the first scan signal GW transmitted through the first scan line SL1 and performs a switching operation in which the data signal Dm transmitted through the data line DL is transmitted to a first node N1.

The third transistor T3 is electrically connected to the first scan line SL1 and electrically connected to the light-emitting diode LED via the sixth transistor T6. The third transistor T3 may be turned on in response to the first scan signal GW transmitted through the first scan line SL1 and may diode-connect the first transistor T1.

The fourth transistor T4 is a first initialization transistor and electrically connected to the third scan line SL3 and the first initialization voltage line VIL1. The fourth transistor T4 is turned on in response to a third scan signal GI transmitted through the third scan line SL3 and is configured to transmit the first initialization voltage Vint from the first initialization voltage line VIL1 to the gate electrode of the first transistor T1, thereby initializing a voltage at the gate electrode of the first transistor T1. The third scan signal GI may correspond to a first scan signal of another pixel driving circuit unit arranged in a previous row of the corresponding pixel driving circuit unit PC.

The fifth transistor T5 may be an operation control transistor, and the sixth transistor T6 may be an emission control transistor. The fifth transistor T5 and the sixth transistor T6 are electrically connected to the emission control line EML and simultaneously turned on according to an emission control signal EM transmitted through the emission control line EML, thus forming a current path to allow the driving current to flow from the first voltage line VDDL to the light-emitting diode LED.

The seventh transistor T7 may be a second initialization transistor and electrically connected to the second scan line SL2, the second initialization voltage line VIL2, and the sixth transistor T6. The seventh transistor T7 may be turned on in response to a second scan signal GB transmitted through the second scan line SL2 and may be configured to transmit the second initialization voltage Vaint from the second initialization voltage line VIL2 to the first electrode of the light-emitting diode LED, thereby initializing the first electrode of the light-emitting diode LED.

The storage capacitor Cst includes a first electrode CE1 and a second electrode CE2. The first electrode CE1 is electrically connected to the gate electrode of the first transistor T1, and the second electrode CE2 is electrically connected to the first voltage line VDDL. The storage capacitor Cst may store and maintain a voltage corresponding to a difference in voltages of the first voltage line VDDL and both ends of the gate electrode of the first transistor T1 so that the voltage applied to the gate electrode of the first transistor T1 may be maintained.

Referring to FIG. 7C, the pixel driving circuit unit PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel driving circuit unit PC is electrically connected to the signal lines and the voltage lines. The signal lines may include gate lines, such as a first scan line SL1, a second scan line SL2, a third scan line SL3, and an emission control line EML, and a data line DL. The voltage lines may include a first initialization voltage line VIL1, a second initialization voltage line VIL2, a sustaining voltage line VSL, and a first voltage line VDDL.

The first voltage line VDDL may be configured to transmit the first power voltage VDD to the first transistor T1. The first initialization voltage line VIL1 may be configured to transmit, to the pixel driving circuit unit PC, a first initialization voltage Vint configured to initialize the first transistor T1. The second initialization voltage line VIL2 may be configured to transmit, to the pixel driving circuit unit PC, a second initialization voltage Vaint configured to initialize the first electrode of the light-emitting diode LED. The sustaining voltage line VSL may provide a sustaining voltage VSUS to a second node N2, for example, the second electrode CE2 of the storage capacitor Cst, in an initialization section and a data writing section.

The first transistor T1 may be electrically connected to the first voltage line VDDL via the fifth transistor T5 and the eighth transistor T8 and to the light-emitting diode LED via the sixth transistor T6. The first transistor T1 may function as a driving transistor and receive a data signal Dm according to a switching operation of the second transistor T2, thereby providing a driving current to the light-emitting diode LED.

The second transistor T2 is electrically connected to the first scan line SL1 and the data line DL and electrically connected to the first voltage line VDDL via the fifth transistor T5 and the eighth transistor T8. The second transistor T2 is turned on in response to the first scan signal GW transmitted through the first scan line SL1 and performs a switching operation in which the data signal Dm transmitted through the data line DL is transmitted to the first node N1.

The third transistor T3 is electrically connected to the first scan line SL1 and electrically connected to the light-emitting diode LED via the sixth transistor T6. The third transistor T3 may be turned on in response to the first scan signal GW transmitted through the first scan line SL1 and diode-connect the first transistor T1, thus compensating for a threshold voltage of the first transistor T1.

The fourth transistor T4 is electrically connected to the third scan line SL3 and the first initialization voltage line VIL1, turned on in response to a third scan signal GI transmitted through the third scan line SL3, and configured to transmit the first initialization voltage Vint from the first initialization voltage line VIL1 to the gate electrode of the first transistor T1, thereby initializing the voltage at the gate electrode of the first transistor T1. The third scan signal GI may correspond to a first scan signal of another pixel driving circuit unit arranged in a previous row of the corresponding pixel driving circuit unit PC.

The fifth transistor T5, the sixth transistor T6, and the eighth transistor T8 are electrically connected to the emission control line EML and simultaneously turned on according to the emission control signal EM transmitted through the emission control line EML, thus forming a current path to allow the driving current to flow from the first voltage line VDDL to the light-emitting diode LED.

The seventh transistor T7 may be a second initialization transistor and electrically connected to the second scan line SL2, the second initialization voltage line VIL2, and the sixth transistor T6. The seventh transistor T7 is turned on in response to a second scan signal GB transmitted through the second scan line SL2 and is configured to transmit the second initialization voltage Vaint from the second initialization voltage line VIL2 to the first electrode of the light-emitting diode LED, thereby initializing the first electrode of the light-emitting diode LED.

The ninth transistor T9 may be electrically connected to the second scan line SL2, the second electrode CE2 of the storage capacitor Cst, and the sustaining voltage line VSL. The ninth transistor T9 may be turned on in response to the second scan signal GB transmitted through the second scan line SL2 and may be configured to transmit a sustaining voltage VSUS to the second node N2, for example, the second electrode CE2 of the storage capacitor Cst, in the initialization section and the data writing section.

The eighth transistor T8 and the ninth transistor T9 may each be electrically connected to the second node N2, for example, the second electrode CE2 of the storage capacitor Cst. In some embodiments, the eighth transistor T8 may be turned off and the ninth transistor T9 may be turned on in the initialization section and the data writing section, whereas the eighth transistor T8 may be turned on and the ninth transistor T9 may be turned off in the emission section. In the initialization section and the data writing section, because the sustaining voltage VSUS is transmitted to the second node N2, the uniformity of the luminance (e.g., Long Range Uniformity (LRU)) of the display apparatus may be improved despite a voltage drop in the first voltage line VDDL.

The storage capacitor Cst includes the first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the sustaining voltage line VSL, and the first electrode of the light-emitting diode LED. The auxiliary capacitor Ca may store and maintain the voltage corresponding to the voltage difference between the first electrode of the light-emitting diode LED and the sustaining voltage line VSL while the seventh transistor T7 and the ninth transistor T9 are turned on, thereby preventing the increase in black luminance when the sixth transistor T6 is off.

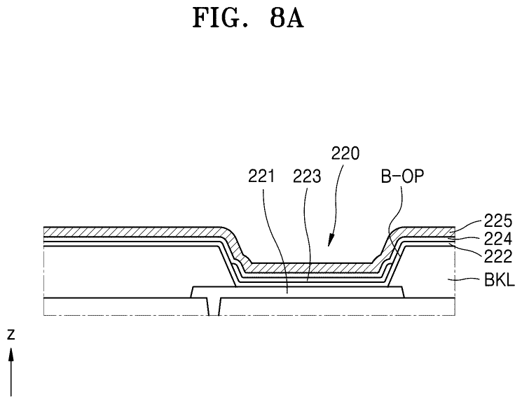

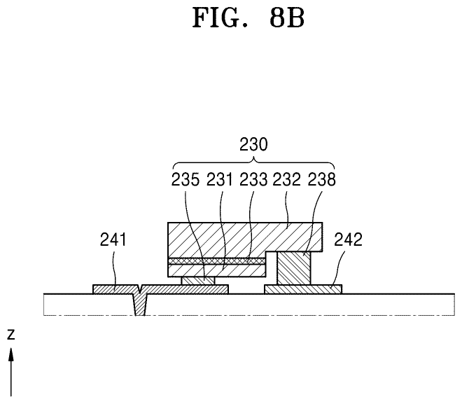

FIG. 8A is a schematic cross-sectional view of a light-emitting diode of a display apparatus, according to an embodiment.

Referring to FIG. 8A, the light-emitting diode LED according to an embodiment may include an organic light-emitting diode 220 including an organic material. The organic light-emitting diode 220 may include a first electrode 221 arranged on an insulating layer, a second electrode 225 facing the first electrode 221, and an emission layer 223 arranged between the first electrode 221 and the second electrode 225. A first functional layer 222 may be arranged between the first electrode 221 and the emission layer 223, and a second functional layer 224 may be arranged between the emission layer 223 and the second electrode 225.

An edge of the first electrode 221 may be covered by a bank layer BKL including an insulating material. The bank layer BKL may include an opening B-OP that overlaps a central portion of the first electrode 221.

The first electrode 221 may include conductive oxide, such as indium tin oxide (ITO), indium zinc oxide (IZO), zinc oxide (ZnO), indium oxide (In₂O₃), indium gallium oxide (IGO), or aluminum zinc oxide (AZO). In an embodiment, the first electrode 221 may include a reflection layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In another embodiment, the first electrode 221 may further include a layer including ITO, IZO, ZnO, AZO, or In₂O₃ over/under the above reflection layer.

The emission layer 223 may include a high-molecular-weight or low-molecular-weight organic material emitting light having a certain color. The first functional layer 222 may include a Hole Transport Layer (HTL) and/or a Hole Injection Layer (HIL). The second functional layer 224 may include an Electron Transport Layer (ETL) and/or an Electron Injection Layer (EIL).

The second electrode 225 may include a conductive material having a low work function. For example, the second electrode 225 may include a transparent (or translucent) layer including Ag, Mg, Al, Pt, Pd, Au, Ni, Nd, Ir, Cr, lithium (Li), calcium (Ca), or an alloy thereof. Alternatively, the second electrode 225 may further include a layer including ITO, IZO, ZnO, AZO, or In₂O₃ on the transparent (or translucent) layer including the above material.

FIG. 8B is a schematic cross-sectional view of a light-emitting diode of a display apparatus, according to an embodiment.

Referring to FIG. 8B, the light-emitting diode LED according to an embodiment may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be and electrically connected to a first electrode pad 241 and a second electrode pad 242 arranged on the same layer, respectively.

In some embodiments, the first semiconductor layer 231 may include a p-type semiconductor layer. The p-type semiconductor layer may be formed of a semiconductor material having the composition formula InₓAl_{y}Ga_{1-x-y}N (0≤x≤1, 0≤y≤1, 0≤x+y≤1), such as GaN, AlN, AlGaN, InGaN, InN, InAlGaN, and AlInN, and may be doped with p-type dopants including Mg, zinc (Zn), Ca, strontium (Sr), and barium (Ba).

The second semiconductor layer 232 may include, for example, an n-type semiconductor layer. The n-type semiconductor layer may be formed of a semiconductor material having the composition formula InₓAl_{y}Ga_{1-x-y}N (0≤x≤1, 0≤y≤1, 0≤x+y≤1), such as GaN, AlN, AlGaN, InGaN, InN, InAlGaN, and AlInN, and may be doped with n-type dopants including silicon (Si), germanium (Ge), and tin (Sn).

The intermediate layer 233 may be a region where electrons and holes are recombined and may transition to a lower energy level as a result of the recombination, thereby generating light having a wavelength corresponding to the transition. The intermediate layer 233 may include a semiconductor material having the composition formula InₓAl_{y}Ga_{1-x-y}N (0≤x≤1, 0≤y≤1, 0≤x+y≤1) and may have a single quantum well structure or a Multi-Quantum Well (MQW) structure. Additionally, the intermediate layer 233 may have a quantum wire structure or a quantum dot structure.

FIG. 8B illustrates that the first semiconductor layer 231 includes a p-type semiconductor layer and the second semiconductor layer 232 includes an n-type semiconductor layer, but the present disclosure is not limited thereto. In another embodiment, the first semiconductor layer 231 may include an n-type semiconductor layer and the second semiconductor layer 232 may include a p-type semiconductor layer.

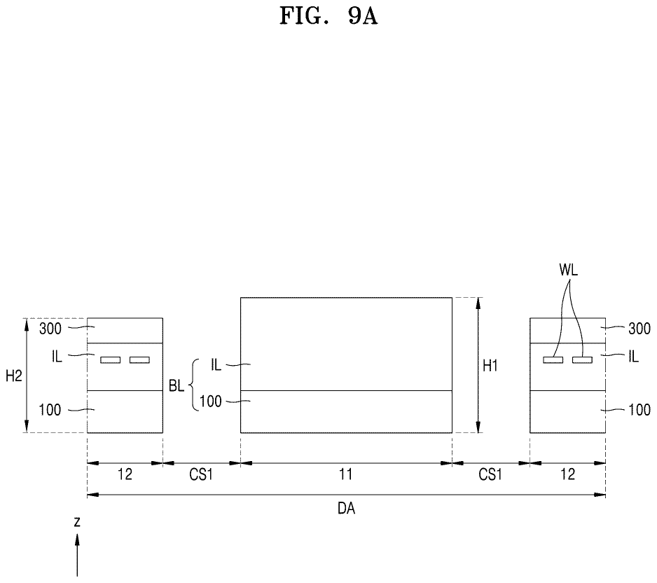

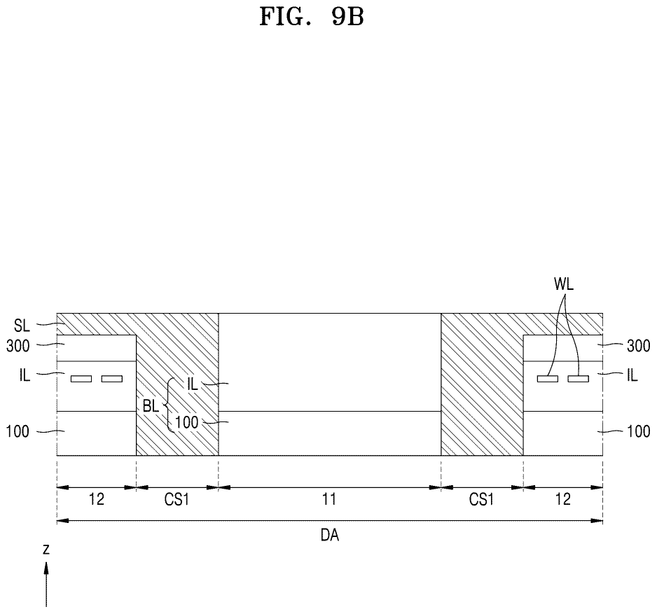

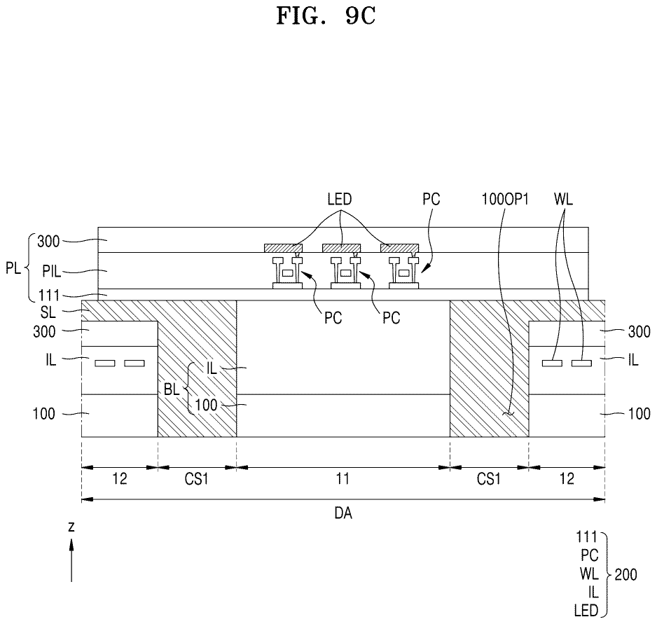

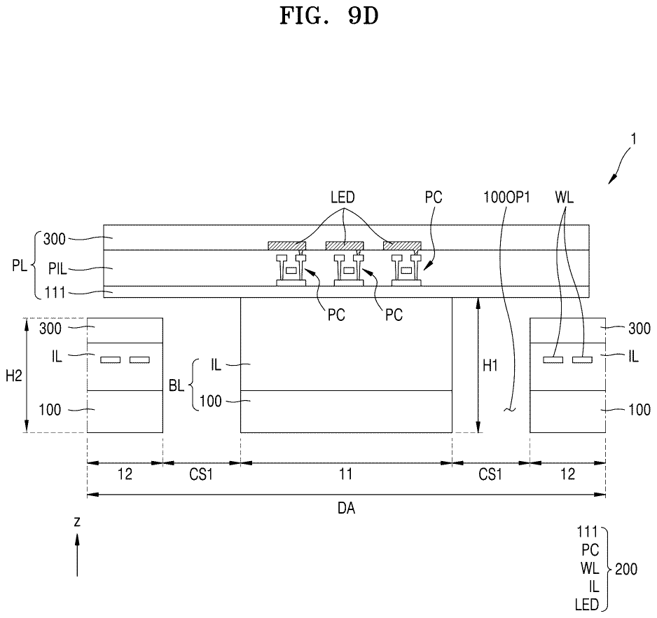

FIGS. 9A to 9D are diagrams schematically illustrating a method of manufacturing a display apparatus, according to an embodiment. The method of manufacturing a display apparatus according to an embodiment may be used to manufacture the display apparatus described above, but the present disclosure is not limited thereto.

Referring to FIG. 9A, the base layers BL and the bridge portions 12 may be arranged. In an embodiment, the base layers BL and the bridge portions 12 may be formed by stacking the insulating layer IL and other layers on the substrate 100. In this case, the thickness H1 of the base layer BL may be greater than the thickness H2 of the bridge portion 12. The base layer BL may be primarily formed of the insulating layer IL, excluding the substrate 100.

Referring to FIG. 9B, a sacrificial layer SL may be deposited. In an embodiment, the sacrificial layer SL may include silicon oxide (SiOx). The sacrificial layer SL may be arranged on portions other than the upper surface of the base layer BL. For example, the sacrificial layer SL may be arranged to fill the first opening portion CS1 and arranged on the upper surface of the bridge portion 12, but may not be arranged on the upper surface of the base layer BL. In other words, the sacrificial layer SL may be deposited to have an opening corresponding to the upper surface of the base layer BL. In this case, the sacrificial layer SL may be deposited to the same height as the base layer BL. For example, the upper surface of the sacrificial layer SL may be located on the same plane as the upper surface of the base layer BL. In other words, the upper surface of the sacrificial layer SL may be flush with the upper surface of the base layer BL

Referring to FIG. 9C, the pixel layer PL may be deposited. In an embodiment, the pixel layer PL may be deposited on the base layer BL and the sacrificial layer SL. That is, the buffer layer 111, the pixel circuit driving unit PC, the insulating layer IL, the light-emitting diode LED, and the encapsulation layer 300 may be sequentially deposited on the upper surface of the base layer BL and the upper surface of the sacrificial layer SL. In this case, the sacrificial layer SL may be located between the upper surface of the bridge portion 12 and the lower surface of the pixel layer PL. In this case, the pixel circuit driving unit PC may be electrically connected to the wires WL arranged in the bridge portion 12 through the contact hole defined in the base layer BL.

In another embodiment, the pixel layer PL may be bonded to the base layer BL and the sacrificial layer SL. That is, the pixel layer PL may be formed by depositing the buffer layer 111, the pixel circuit driving unit PC, the insulating layer IL, the light-emitting diode LED, and the encapsulation layer 300 through a separate process, and the pixel layer PL may be bonded to the base layer BL and the upper surface of the sacrificial layer SL. In this case, the sacrificial layer SL may be located between the upper surface of the bridge portion 12 and the lower surface of the pixel layer PL.

In this case, as described above, it may be understood that the pixel layer PL is arranged to be offset from the base layer BL in a plan view. The description that the pixel layer PL is offset from the base layer BL in a plan view may indicate, for example, that the base layer BL is arranged at a position where the pixel layer PL is rotated by a preset angle around the center C of the pixel layer PL. In this case, it may be understood that the size of the pixel layer PL is greater than the size of the base layer BL.

Referring to FIG. 9D, the sacrificial layer SL may be removed. In an embodiment, the sacrificial layer SL may be removed through wet etching. The sacrificial layer SL, for example, SiOx, may be etched using a hydrofluoric acid (HF) solution. Accordingly, the sacrificial layer SL may be removed, and the pixel layer PL may be spaced apart from the upper surface of the bridge portion 12 and arranged on the upper portion of the first opening portion CS1. In an embodiment, the first opening portion CS1, in which the sacrificial layer SL was present, and the space between the upper surface of the bridge portion 12 and the lower surface of the pixel layer PL may be empty. In another embodiment, the first opening portion CS1, in which the sacrificial layer SL was present, and the space between the upper surface of the bridge portion 12 and the lower surface of the pixel layer PL may be filled again with an elastic material. In this case, the elastic member may be, for example, silicon oil. The elastic member may facilitate the stretching of the island portion 11 and the bridge portion 12.

The display apparatus 1 according to the above embodiments may be used in various electronic devices capable of providing images. Here, an electronic device refers to a device that runs on electricity and provides images.

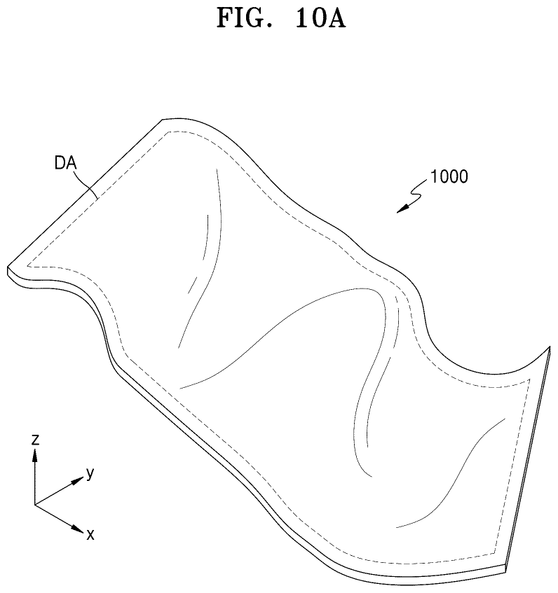

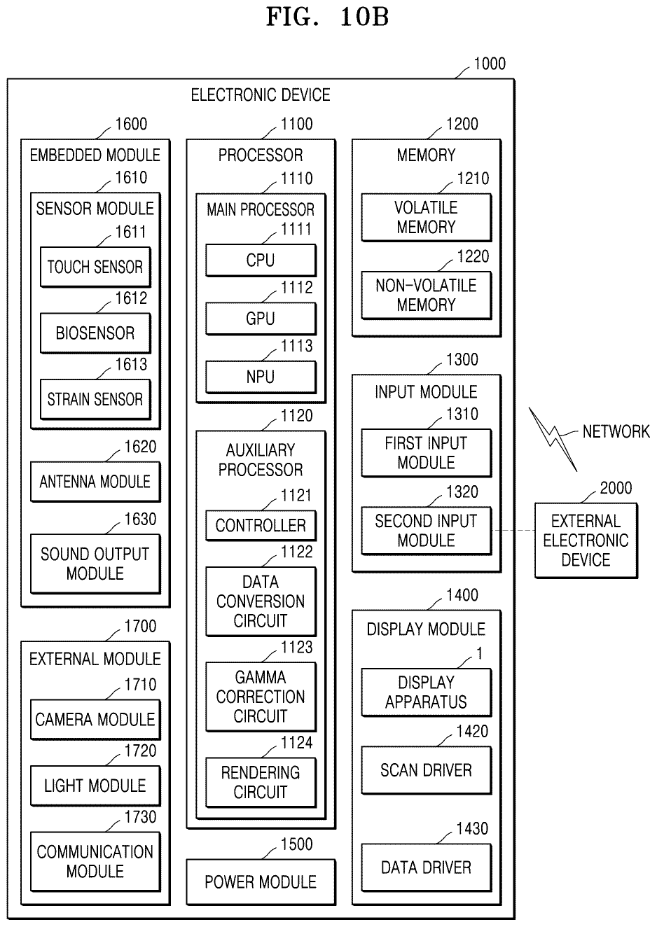

FIG. 10A is a schematic perspective view of an electronic device 1000 including a display apparatus, according to an embodiment, and FIG. 10B is a schematic block diagram of the electronic device 1000 including the display apparatus 1, according to an embodiment.

Referring to FIG. 10A, the electronic device 1000 may undergo free three-dimensional deformation and provide a three-dimensional image plane through the display area DA. The free three-dimensional deformation of the electronic device 1000 is distinguished from the operation of an electronic device including a rollable display apparatus where only a rolled portion of a display area is visible to a user and then the entire display area becomes visible because the rolled portion is unrolled (or the entire unfolded display area is initially visible and then only a portion of the display area is visible to the user as the display area is rolled). The electronic device 1000 according to embodiments may undergo deformation, such as an increase in the area of the entire display area DA, followed by a decrease, as the electronic device 1000 is deformed in the x direction, y direction, and/or z direction.

Referring to FIG. 10B, the electronic device 1000 may include a processor 1100, a memory 1200, an input module 1300, a display module 1400, a power module 1500, an embedded module 1600, and an external module 1700. According to an embodiment, at least one of the above-described components of the electronic device 1000 may be omitted, or one or more additional components may be added. According to an embodiment, some of the aforementioned components (e.g., the embedded module 1600) may be integrated into another component (e.g., the display module 1400).

The processor 1100 may execute software to control at least one component (e.g., a hardware component or a software component) of the electronic device 1000 connected to the processor 1100 and may perform various data processing or computational operations. According to an embodiment, as at least part of the data processing or computational operations, the processor 1100 may store, in volatile memory 1210, commands or data received from other components (e.g., the input module 1300, a sensor module 1610, or a communication module 1730), process the commands or data stored in the volatile memory 1210, and store resulting data in non-volatile memory 1220.

The processor 1100 may include a main processor 1110 and an auxiliary processor 1120. The main processor 1110 may include at least one of a Central Processing Unit (CPU) 1111 and an Application Processor (AP). The main processor 1110 may further include at least one of a Graphics Processing unit (GPU) 1112, a Communication Processor (CP), and an Image Signal Processor (ISP). The main processor 1110 may further include a Neural Processing Unit (NPU) 1113. The NPU 1113 may be a processor that is specialized for operations of an Artificial Intelligence (AI) model, and the AI model may be generated through machine learning. The AI model may include a plurality of artificial neural network layers. The artificial neural network may be one of a Deep Neural Network (DNN), a Convolutional Neural Network (CNN), a Recurrent Neural Network (RNN), a Restricted Boltzmann Machine (RBM), a Deep Belief Network (DBN), a Bidirectional Recurrent Deep Neural Network (BRDNN), deep Q-networks, and a combination of at least two of the aforementioned types, but is not limited thereto. In addition to a hardware structure, the AI model may additionally or generally include a software structure. At least two of the processing units and processors stated above may be implemented as a single integrated component (e.g., a single chip) or as individual components (e.g., multiple chips).

The auxiliary processor 1120 may include a controller 1121. The controller 1121 may include an interface conversion circuit and a timing control circuit. The controller 1121 may receive image signals from the main processor 1110 and convert the data format of the image signals to comply with the interface specification with the display module 1400, thus outputting image data. The controller 1121 may output various control signals required for the operation of the display module 1400.

The auxiliary processor 1120 may further include data processing circuits, such as a data conversion circuit 1122, a gamma correction circuit 1123, and a rendering circuit 1124. The data conversion circuit 1122 may receive image data from the controller 1121 and may adjust the image data to display images at a desired luminance according to the characteristics of the electronic device 1000 or the user's settings or may convert the image data to reduce power consumption or compensate for afterimages. The gamma correction circuit 1123 may convert image data, a gamma reference voltage, or the like to ensure that the images displayed on the electronic device 1000 exhibit desired gamma characteristics. The rendering circuit 1124 may receive image data from the controller 1121 and perform rendering on the image data by considering pixel arrangements in the display apparatus 1 applied to the electronic device 1000. At least one of the data conversion circuit 1122, the gamma correction circuit 1123, and the rendering circuit 1124 may be integrated into other components (e.g., the main processor 1110 or the controller 1121). In an embodiment, the auxiliary processor 1120 may be integrated into a data driver 1430.

The memory 1200 may store various pieces of data used by at least one component (e.g., the processor 1100 or the sensor module 1610) of the electronic device 1000 and input data or output data regarding commands associated with the data. The memory 1200 may include at least one or more of the volatile memory 1210 and the non-volatile memory 1220.

The input module 1300 may receive commands or data, which are to be used by a component (e.g., the processor 1100, the sensor module 1610, or the sound output module 1630) of the electronic device 1000, from the outside of the electronic device 1000 (e.g., from the user or an external electronic device 2000).

The input module 1300 may include a first input module 1310, to which commands or data from the user are input, and a second input module 1320, to which commands or data from the external electronic device 2000 are input.

The first input module 1310 may include a microphone, a mouse, a keyboard, or a pen (e.g., a passive pen or an active pen). The first input module 1310 may include a mechanical input medium, such as buttons located on the rear surface or side surfaces of the electronic device 1000, a dome switch, a jog wheel, or a jog switch, or a touch input medium. The touch input medium may include a touch screen layer of the display apparatus 1.

The second input module 1320 may connect to various types of electronic devices 2000 connected to the electronic device 1000 in a wired or wireless manner. According to an embodiment, the second input module 1320 may include, for example, a High Definition Multimedia Interface (HDMI), a Universal Serial Bus (USB) interface, a Secure Digital (SD) card interface, or an audio interface. The second input module 1320 may include a connector physically connecting the electronic device 1000 to the external electronic device 2000, for example, an HDMI connector, a USB connector, an SD card connector, or an audio connector (e.g., a headphone connector). The electronic device 1000 may perform appropriate controls related to the external electronic device 2000, in accordance with the connection of the external electronic device 2000 to the second input module 1320.

The display module 1400 visually provides information to the user. The display module 1400 may include the display apparatus 1, a scan driver 1420, and a data driver 1430.

The display apparatus 1 displays (outputs) information processed by the electronic device 1000. The display apparatus 1 may display information regarding an execution screen of an application executed on the electronic device 1000, or User Interface (UI) information or Graphics User Interface (GUI) information according to the information regarding the execution screen.

The scan driver 1420 may be mounted on the display apparatus 1 as a driving chip. Alternatively, the scan driver 1420 may be directly formed on the display apparatus 1. For example, the scan driver 1420 may include an Amorphous Silicon TFT Gate driver circuit (ASG), a Low Temperature Polycrystalline Silicon (LTPS) TFT Gate driver circuit, or an Oxide Semiconductor TFT Gate driver circuit (OSG) embedded in the display apparatus 1. The scan driver 1420 receives control signals from the controller 1121 and outputs scan signals to the display apparatus 1 in response to the control signals.

The display apparatus 1 may further include an emission control driver. The emission control driver outputs emission control signals to the display apparatus 1 in response to the control signals received from the controller 1121. The emission control driver may be formed either separately from the scan driver 1420 or integrally with the same.

The data driver 1430 receives control signals from the controller 1121, converts image data into data voltages in the form of analog voltages in response to the control signals, and then outputs the data voltages to the display apparatus 1.

The data driver 1430 may be integrated with some components of the auxiliary processor 1120. For example, the data driver 1430 may be included as a timing controller embedded driver integrated circuit (IC) including the controller 1121.

The power module 1500 supplies power to the components of the electronic device 1000. The power module 1500 may include a battery that charges a power voltage. In addition, the power module 1500 may include a connection port, and the connection port may be included in the second input module 1320 that is connected to an external charger for supplying power to charge the battery. Alternatively, the power module 1500 may include a wireless power transceiver member to charge the battery in a wireless manner. The wireless power transceiver member may include a plurality of coil-shaped antenna radiators. The power module 1500 may include a Power Management Integrated Circuit (PMIC). The PMIC supplies power that is optimized for each component of the electronic device 1000.

The electronic device 1000 may further include the embedded module 1600 and the external module 1700. The embedded module 1600 may include the sensor module 1610, the antenna module 1620, and the sound output module 1630. The external module 1700 may include a camera module 1710, a light module 1720, and/or a communication module 1730.

The sensor module 1610 may include touch electrodes and a touch sensor driver of the touch screen layer of the display apparatus 1. The sensor module 1610 may sense input from the user's body or a pen and generate an electrical signal or a data value corresponding to the input. The sensor module 1610 may include at least any one of a touch sensor 1611, a biosensor 1612, and a strain sensor 1613.

The touch sensor 1611 may generate a data value corresponding to coordinate information of input from the user's body (e.g., a finger, etc.) or a pen. The touch sensor 1611 may generate, as data values, variations in capacitance, pressure, or electromagnetic properties.

The biosensor 1512 may generate data values used to recognize a body part of the user (e.g., fingerprint, iris, face, etc.) or data values corresponding to information about the user's body (e.g., blood pressure, hydration level, heart rate, body composition, etc.). The biosensor 1512 may utilize an optical, ultrasonic, or capacitive method.

The strain sensor 1613 may include layers, patterns, or wires of which measurable physical quantities change according to the stretching and recovery of the display apparatus 1. For example, the strain sensor 1613 may include wires of which resistance and/or capacitance change according to the stretching and recovery of the display apparatus 1. In another embodiment, the strain sensor 1613 may include an optical layer or an optical pattern of which transmittance and/or reflectivity change according to the stretching and recovery of the display apparatus 1.

Based on the change in the physical quantities according to the stretching and recovery of the display apparatus 1 measured by the strain sensor 1613, the electronic device 1000 may improve the quantity of images implemented on the display apparatus 1 or may control the display apparatus 1. The control operation of the display apparatus 1 may include, for example, displaying a motion image for protecting the display apparatus 1, blocking a voltage for driving the display apparatus 1, or stopping a stretching and recovering operation of the display apparatus 1.

In an embodiment, at least one of the touch sensor 1611, the biosensor 1612, and the strain sensor 1613 may be embedded in the display apparatus 1. For example, at least one of the touch sensor 1611, the biosensor 1612, and the strain sensor 1613 may be formed through a process that follows the process of forming the pixel driving circuit unit and/or the light-emitting diode of the display apparatus 1. To this end, the display apparatus 1 may function as one of the input modules 1300 for providing an input interface between the electronic device 1000 and the user while functioning as the display module 1400 for providing an output interface between the electronic device 1000 and the user.

In an embodiment, at least two of the touch sensor 1611, the biosensor 1612, and the strain sensor 1613 may be integrated into a single sensing panel through the same process. In an embodiment, the sensing panel may be arranged between the display apparatus 1 and a window cover arranged on the front surface of the display apparatus 1, but the present disclosure is not limited thereto.

The antenna module 1620 may include one or more antennas for transmitting signals or power to the outside or receiving the same from the outside. According to an embodiment, the communication module 1730 may transmit a signal to an external electronic device or receive the signal therefrom through the antenna that is suitable for the communication method. An antenna pattern of the antenna module 1620 may be integrated into a component (e.g., the display apparatus 1) of the display module 1400 or the biosensor 1612.

The sound output module 1630 may be a device for outputting sound signals to the exterior of the electronic device 1000 and may output sound data that is received from the communication module 1730 or stored in the memory 1200 in a call signal reception mode, a call or recording mode, a voice recognition mode, a broadcast reception mode, or the like. The sound output module 1630 may output sound signals related to functions performed by the electronic device 1000 (e.g., call signal receiving sound, message notification sound, etc.). The sound output module 1630 may include a receiver and a speaker. At least one of the receiver and the speaker may be a sound generating device that is attached to the rear surface of the display apparatus 1 and outputs sound by vibrating the display apparatus 1. The sound generating device may be a piezoelectric element or a piezoelectric actuator that contracts and expands according to electrical signals or may be an exciter that generates magnetic force using voice coils and vibrates the display apparatus 1.

The camera module 1710 may capture still and moving images. According to an embodiment, the camera module 1710 may include one or more lenses, an image sensor, or an ISP. The camera module 1710 may further include an infrared camera that may detect the user's presence, location, gaze, and the like.

The light module 1720 may output a signal to notify the occurrence of events by using light from a light source or may provide light for image acquisition. Here, examples of the occurrence of events may include message reception, call signal reception, missed calls, notifications, schedule notifications, e-mail reception, and battery capacity information notifications. The light module 1720 may include light-emitting diodes or a xenon lamp. The light module 1720 may emit light of a single color or different colors to the front surface or rear surface of the electronic device 1000. The light module 1720 may operate in conjunction with or independently from the camera module 1710.

The communication module 1730 may support the establishment of wired or wireless communication channels between the electronic device 1000 and the external electronic device 2000 and support communication through the established communication channels. The communication module 1730 may include any one or all of a wireless communication module, such as a cellular communication module, a short-range wireless communication module, or a Global Navigation Satellite System (GNSS) communication module, and a wired communication module, such as a Local Area Network (LAN) communication module or a power line communication module. The communication module 1730 may receive/transmit wireless signals from/to the Internet using at least one of Wireless LAN (WLAN), Wireless-Fidelity (Wi-Fi), Wi-Fi Direct, and Digital Living Network Alliance (DLNA) technologies. In addition, the communication module 1730 may support short-range communication by using at least one of Bluetooth™, Radio Frequency Identification (RFID), Infrared Data Association (IrDA), Ultra-Wideband (UWB), ZigBee, Near Field Communication (NFC), Wi-Fi, Wi-Fi Direct, and Wireless USB technologies. Various types of communication modules 1730 described above may be implemented as a single chip or separate chips.

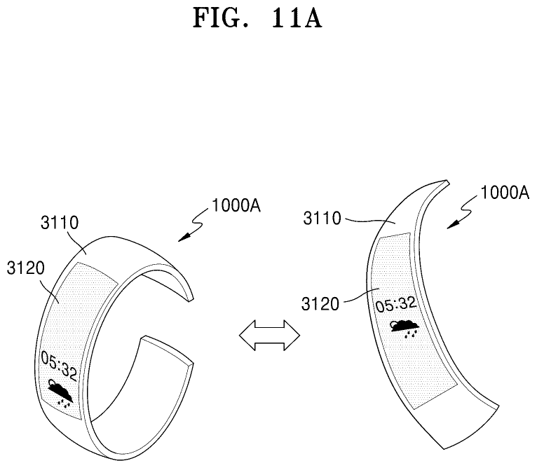

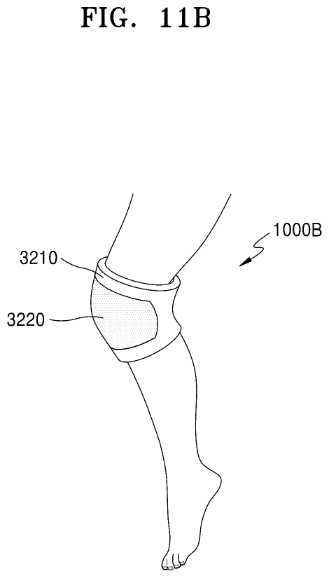

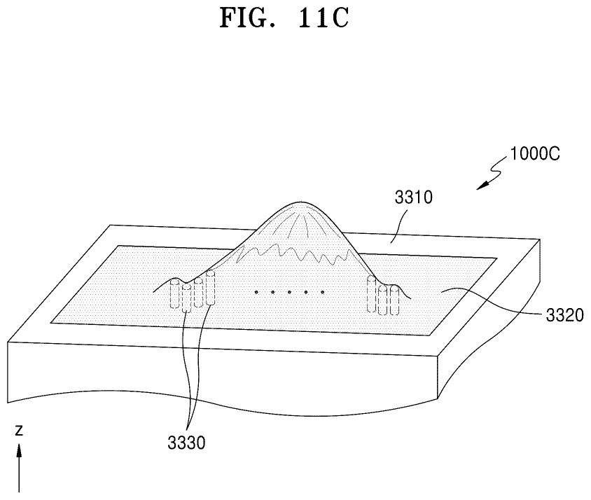

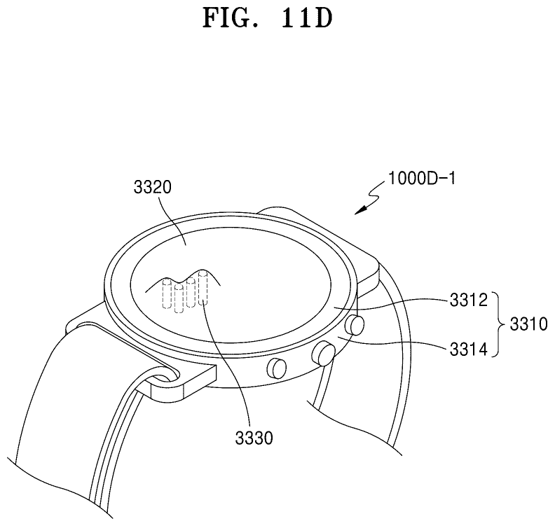

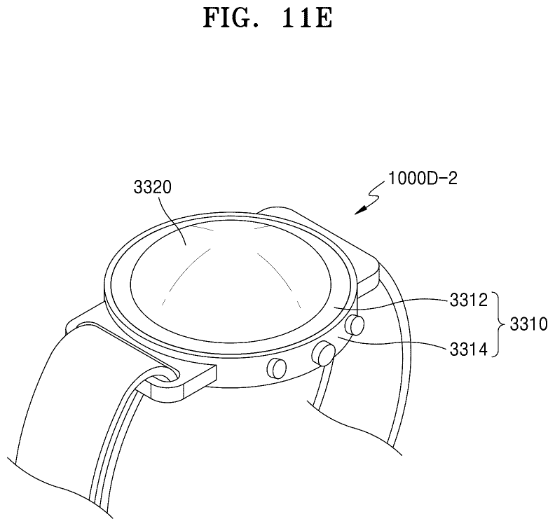

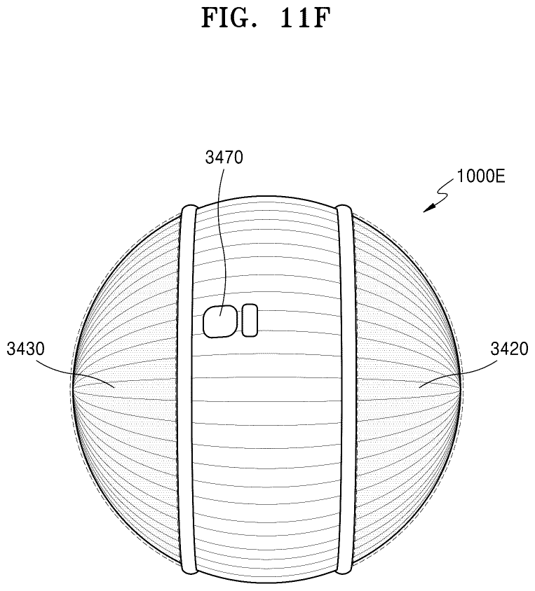

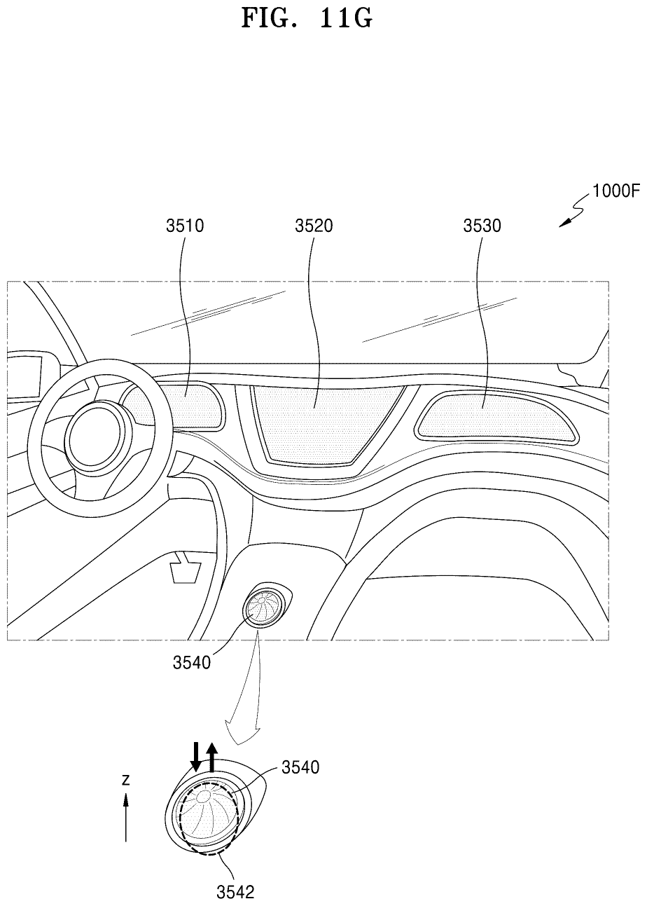

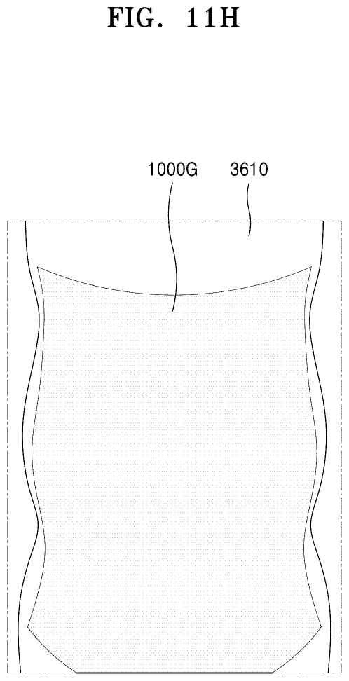

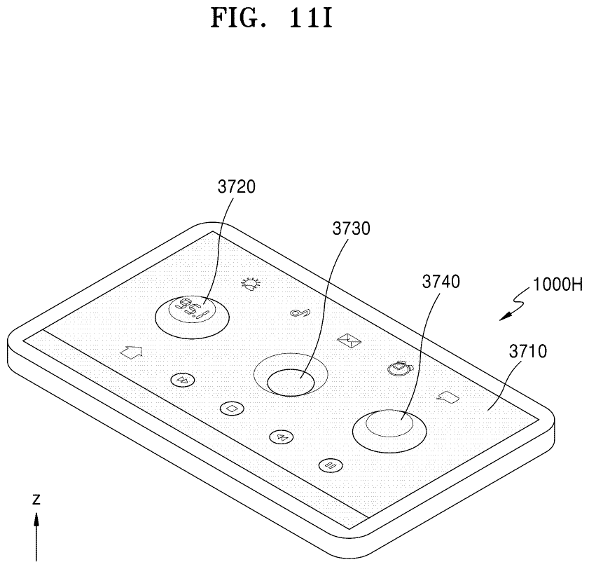

FIGS. 11A to 11I are schematic perspective views showing embodiments of electronic devices including display apparatuses, respectively, according to an embodiment.

Referring to FIG. 11A, the display apparatus according to an embodiment may be applied to a wearable electronic device 1000A that may be worn on a body part of the user. The wearable electronic device 1000A may include a body portion 3110 and a display unit 3120 included in the body portion 3110. The display apparatus according to embodiments may be used as the display unit 3120 of the wearable electronic device 1000A. The wearable electronic device 1000A shown in FIG. 11A may be deformable. In an embodiment, depending on the selection of the user, the wearable electronic device 1000A may be used as a smart watch or a smartphone.

FIG. 11B illustrates a medical electronic device 1000B. In an embodiment, the medical electronic device 1000B may include a body portion 3210 and an emission portion 3220. The display apparatus according to embodiments may be used as the emission portion 3220 of the medical electronic device 1000B. The emission portion 3220 may irradiate light in a specific wavelength band (e.g., infrared light, visible light, etc.) onto a body part of a patient. In an embodiment, the body portion 3210 may include a stretchable and recoverable fiber material and have a structure wearable on the body of the user.

FIG. 11C illustrates an educational electronic device 1000C. In an embodiment, the educational electronic device 1000C may include a display unit 3320 included in a body portion 3310. The display unit 3320 may use a display apparatus according to embodiments. Through the display unit 3320, images such as an ocean with waves, a mountain covered in snow, or a volcano with flowing lava may be provided, and in this case, the display unit 3320 may be stretched in the thickness direction (e.g., the z direction) by reflecting the height of the ocean, mountain, or volcano. In some embodiments, portions of the display unit 3320 may sequentially vary in height along the direction in which the lava flows, and thus, the lava movement may be three-dimensionally displayed. The educational electronic device 1000C may include a plurality of pins (or strokes) 3330 arranged on the rear surface of the display unit 3320 to allow the display unit 3320 to be stretched in the thickness direction. As the pins 3330 move along the third direction (e.g., the z direction or −z direction), the image displayed by the display unit 3320 may be implemented to have a three-dimensional height. FIG. 11C illustrates the educational electronic device 1000c, but the usage thereof is not limited as long as specific image information is provided.

FIGS. 11D and 11E illustrate that display apparatuses are applied to wearable electronic devices 1000D-1 and 1000D-2, such as smart watches.

In an embodiment, as shown in FIG. 11D, the display apparatus corresponding to a display unit 3320 of the electronic device 1000D-1 is three-dimensionally stretchable and thus may provide various types of haptic information to the user in addition to visual information based on the image. In an embodiment, the electronic device 1000D-1 may provide haptic information, such as braille for the visually impaired or tactile stimuli linked to an image, by using pins (or strokes) 3330 arranged under the display unit 3320. Because the display apparatus forming the display unit 3320 is stretchable in three dimensions, the aforementioned haptic information may be provided to the user. The electronic device 1000D-1 may include a housing 3314 for accommodating the display apparatus forming the display unit 3320 and the pins (or strokes) 3330, and also include a body portion 3310 including a frame 3312 that may be coupled to the housing 3314 with the display apparatus therebetween. In some embodiments, the frame 3312 may be formed integrally with the housing 3314.

The electronic device 1000D-2 of FIG. 11E may include a body portion 3310 and a display unit 3320 that is accommodated in the body portion 3310 and provides visual information. In some embodiments, because the display apparatus corresponding to the display unit 3320 is stretchable in three-dimensions, the display apparatus may include the display unit 3320 having a dome shape. In an embodiment, the display apparatus may be assembled onto a dome-shaped body frame during the manufacturing process of the electronic device 1000D-2, and in this case, because the display apparatus is three-dimensionally stretchable, the display apparatus may be assembled along the shape of the hemispherical body frame.

FIG. 11F illustrates that an electronic device 1000E includes a robot, according to an embodiment. The robot may move or recognize objects using a camera module 3470 and may provide certain images to the user through display units 3420 and 3430.

In some embodiments, because the display apparatuses according to an embodiment may be stretched in various directions as described above, the display apparatuses may be assembled onto hemispherical body frames; thus, the robot may include the display units 3420 and 3430 having hemispherical shapes.

FIG. 11G illustrates a display apparatus 1000F for a vehicle as an electronic device, according to an embodiment. The display apparatus 1000F may include a cluster 3510, a Center Information Display (CID) 3520, and/or a co-driver display 3530. Because the display apparatus according to an embodiment is stretchable in various directions, the display apparatus may be used in the cluster 3510, the CID 3520, and/or the co-driver display 3530 without being limited by the shape of an internal frame of the vehicle.

FIG. 11G illustrates that the cluster 3510, the CID 3520, and/or the co-driver display 3530 are separately placed from each other, but the present disclosure is not limited thereto. In another embodiment, at least two selected from among the cluster 3510, the CID 3520, and the co-driver display 3530 may be integrally formed.

In some embodiments, the display apparatus 1000F for a vehicle may include a button 3540 capable of implementing specific images. When the enlarged view of FIG. 11G is examined, the button 3540 having a hemispherical shape may include an object 3542 and a display apparatus arranged on the object 3542, wherein the object 3542 provides tactile feedback of the button 3540 while moving in the z direction or −z direction. In some embodiments, when the object 3542 has a three-dimensionally curved surface, the display apparatus may also have a three-dimensionally curved surface.

FIG. 11H illustrates an electronic device 1000G is an electronic device for advertising or display purposes, according to an embodiment. In some embodiments, the electronic device 1000G for advertising or display may be installed on a fixed structure 3610, such as a wall or a column. When the fixed structure 3610 includes an uneven surface as shown in FIG. 11H, the electronic device 1000G for a billboard or an exhibition may also be arranged along the uneven surface of the fixed structure 3610. In some embodiments, the electronic device 1000G for advertising or display may be installed on the fixed structure 3610 by using a thermally shrinkable film or the like.

FIG. 11I illustrates that an electronic device 1000H is a controller, according to an embodiment. The controller may include image-type buttons. For example, the controller may include a first button region 3720 to a third button region 3740 that partially protrude in the z direction or −z direction (or are recessed in the z direction). In some embodiments, the first button region 3720 and the third button region 3740 may protrude in the z direction, and the second button region 3730 may protrude in the −z direction (or be recessed in the z direction).

While the present disclosure has been particularly shown and described with reference to embodiments thereof, it will be understood by one of ordinary skill in the art that various changes in form and details may be made therein without departing from the spirit and scope of the present disclosure as defined by the following claims.

### EXPLANATION OF REFERENCE NUMERALS DESIGNATING THE MAJOR ELEMENTS OF THE DRAWINGS

1: DISPLAY APPARATUS
11: ISLAND PORTION
BL: BASE LAYER
PL: PIXEL LAYER
12: BRIDGE PORTION
100: SUBSTRATE
PC: PIXEL DRIVING CIRCUIT UNIT
LED: LIGHT-EMITTING DIODE
WL: WIRE

What is claimed is:

1. A display apparatus comprising:
an island portion in which a light-emitting diode is arranged; and
a bridge portion connecting the island portion to an adjacent another island portion,
wherein the island portion comprises:
a base layer directly connected to the bridge portion; and
a pixel layer arranged on the base layer and overlapping both the base layer and at least a portion of the bridge portion in a plan view.

2. The display apparatus of claim 1, wherein a lower surface of the pixel layer is connected to an upper surface of the base layer and spaced apart from an upper surface of the bridge portion.

3. The display apparatus of claim 2, wherein a space between the lower surface of the pixel layer and the upper surface of the bridge portion is filled with an elastic member.

4. The display apparatus of claim 1, wherein, in the pixel layer, the light-emitting diode and a pixel driving circuit unit, electrically connected to the light-emitting diode and which drives the light-emitting diode, are arranged.

5. The display apparatus of claim 4, wherein the pixel driving circuit unit is electrically connected to wires arranged in the bridge portion through a contact hole in the base layer.

6. The display apparatus of claim 1, wherein a side of the pixel layer and a side of the base layer, which corresponds to the side of the pixel layer, are obliquely inclined with respect to each other in the plan view.

7. The display apparatus of claim 1, wherein the pixel layer is provided in plurality, and the plurality of pixel layers are arranged parallel to each other in a first direction, and
a side of each of the plurality of pixel layers is parallel to the first direction.

8. The display apparatus of claim 7, wherein a side of the base layer is obliquely inclined with respect to the first direction in the plan view.

9. The display apparatus of claim 1, wherein, in the plan view, a size of the pixel layer is greater than a size of the base layer.

10. The display apparatus of claim 1, wherein a thickness of the base layer is greater than a thickness of the bridge portion.

11. The display apparatus of claim 1, wherein the base layer comprises a substrate and an insulating layer arranged on the substrate.

12. A method of manufacturing a display apparatus, the method comprising:
arranging a base layer and a bridge portion directly connected to the base layer;
depositing a sacrificial layer over regions other than an upper surface of the base layer;
arranging a pixel layer on an upper surface of the base layer and an upper surface of the sacrificial layer; and
removing the sacrificial layer.

13. The method of claim 12, wherein the arranging of the pixel layer comprises arranging the pixel layer to overlap both the base layer and at least a portion of the bridge portion in a plan view.

14. The method of claim 12, wherein the removing of the sacrificial layer comprises spacing a lower surface of the pixel layer apart from an upper surface of the bridge portion.

15. The method of claim 12, wherein, in the pixel layer, a light-emitting diode and a pixel driving circuit unit, electrically connected to the light-emitting diode and which drives the light-emitting diode, are arranged.

16. The method of claim 15, wherein the arranging of the pixel layer comprises electrically connecting the pixel driving circuit unit to wires, which are arranged in the bridge portion, through a contact hole in the base layer.

17. The method of claim 12, wherein, the arranging of the pixel layer comprises arranging a side of the pixel layer and a side of the base layer, which corresponds to the side of the pixel layer, to be obliquely inclined with respect to each other in a plan view.

18. The method of claim 12, wherein the pixel layer is provided in plurality, and the plurality of pixel layers are arranged parallel to each other in a first direction, and
a side of each of the plurality of the pixel layer is arranged parallel to the first direction.

19. The method of claim 18, wherein a side of the base layer is obliquely inclined with respect to the first direction in a plan view.

20. An electronic device comprising:
a display apparatus, which displays an image; and
a housing, which accommodates the display apparatus,
wherein the display apparatus comprises:
an island portion in which a light-emitting diode is arranged; and
a bridge portion connecting the island portion to an adjacent another island portion, and
wherein the island portion comprises:
a base layer directly connected to the bridge portion; and
a pixel layer arranged on the base layer and overlapping the base layer and at least a portion of the bridge portion in a plan view.
